(19) United States
(12) Patent Application Publication
(10) Pub. No.: US 2025/0318119 A1
(43) Pub. Date: Oct. 9, 2025

(54) METHOD OF MAKING THREE-DIMENSIONAL MEMORY DEVICE WITH COMPACT STAIRCASE

(71) Applicant: SANDISK TECHNOLOGIES LLC, ADDISON, TX (US)

(72) Inventors: Masato NOGUCHI, Yokkaichi (JP); Toru TODA, Yokkaichi (JP)

(21) Appl. No.: 18/629,422

(22) Filed: Apr. 8, 2024

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80006; H01L 2224/80895; H01L 2224/80896; H01L 2924/1431; H01L 2924/14511

(57) ABSTRACT

A device structure can be formed by forming an alternating stack of insulating layers and spacer material layers over a substrate, the alternating stack including a rectangular contact region having a shape of a rectangular area in a plan view, forming at least one lengthwise step laterally extending along a first horizontal direction between a pair of widthwise sides of the rectangular area of the alternating stack, and forming a plurality of widthwise steps laterally extending along a second horizontal direction between a pair of lengthwise sides of the rectangular area of the alternating stack by performing multiple instances of a stepped surface formation processing sequence.

### FIELD

The present disclosure relates generally to the field of semiconductor devices, and particularly to a three-dimensional memory device containing a compact staircase and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a method of forming a device structure is provided. The method comprises: forming an alternating stack of insulating layers and spacer material layers over a substrate, wherein the spacer material layers are formed as or are subsequently replaced with electrically conductive layers, wherein the alternating stack comprises a contact region comprising a rectangular area in a plan view and a surrounding area that surrounds the rectangular area, wherein the rectangular area comprises a periphery including a pair of lengthwise sides laterally extending along a first horizontal direction and a pair of widthwise sides laterally extending along a second horizontal direction in a plan view; forming at least one lengthwise step laterally extending along the first horizontal direction between the pair of widthwise sides of the rectangular area of the alternating stack, wherein each horizontal surface segment within the rectangular area of the alternating stack is formed at M different levels, wherein M is an integer in a range from 2 to 6; and forming a plurality of widthwise steps laterally extending along the second horizontal direction between the pair of lengthwise sides of the rectangular area of the alternating stack by performing multiple instances of a stepped surface formation processing sequence, wherein each instance of the stepped surface formation processing sequence comprises a respective masking process in which a respective photoresist layer is applied over the alternating stack and is lithographically patterned to partially mask the rectangular area and completely mask the surrounding area and to provide a respective sidewall that extends over the rectangular area along the second horizontal direction, a respective anisotropic etch process that etches respective portions of the alternating stack that are not masked by the respective photoresist layer by a respective recess etch depth, and a respective photoresist removal process that removes the respective photoresist layer.

### BRIEF DESCRIPTION OF THE DRAWINGS

FIG. 1 is a schematic vertical cross-sectional view of an exemplary structure after formation of an alternating stack of insulating layers and sacrificial material layers over a carrier substrate according to an embodiment of the present disclosure.

FIGS. 2A-11C illustrate a first sequence of manufacturing processes that may be employed to form a contact well having a first configuration according to a first embodiment of the present disclosure. Each figure is labeled with a combination of figure numeral and a suffix selected from A, B, and C. Within FIGS. 2A-11C, figures labeled with the suffix “C” represent top-down views; figures labeled with the suffix “A” represent a vertical cross-sectional view along a vertical plane A-A′ in a figure having a same figure numeral; and figures labeled with the suffix “B” represent a vertical cross-sectional view along a vertical plane B-B′ in a figure having a same figure numeral.

FIGS. 2A-2C are various views of a region of the exemplary structure after formation of a first patterned photoresist layer over a rectangular area according to an embodiment of the present disclosure.

FIGS. 3A-3C are various views of a region of the exemplary structure after performing a first anisotropic etch process according to an embodiment of the present disclosure.

FIGS. 4A-4C are various views of a region of the exemplary structure after formation of a second patterned photoresist layer over a rectangular area according to an embodiment of the present disclosure.

FIGS. 5A-5C are various views of a region of the exemplary structure after performing a second anisotropic etch process according to an embodiment of the present disclosure.

FIGS. 6A-6C are various views of a region of the exemplary structure after formation of a third patterned photoresist layer over a rectangular area according to an embodiment of the present disclosure.

FIGS. 7A-7C are various views of a region of the exemplary structure after performing a third anisotropic etch process according to an embodiment of the present disclosure.

FIGS. 8A-8C are various views of a region of the exemplary structure after formation of a fourth patterned photoresist layer over a rectangular area according to an embodiment of the present disclosure.

FIGS. 9A-9C are various views of a region of the exemplary structure after performing a fourth anisotropic etch process according to an embodiment of the present disclosure.

FIGS. 10A-10C are various views of a region of the exemplary structure after formation of a fifth patterned photoresist layer over a rectangular area according to an embodiment of the present disclosure.

FIGS. 11A-11C are various views of a region of the exemplary structure after performing a fifth anisotropic etch process according to an embodiment of the present disclosure.

FIGS. 12A-23D illustrate a second sequence of manufacturing processes that may be employed to form a contact well having a second configuration according to a second embodiment of the present disclosure. Each figure is labeled with a combination of figure numeral and a suffix selected from A, B, C, and D. Within FIGS. 12A-23D, figures labeled with the suffix “D” represent top-down views; figures labeled with the suffix “A” represent a vertical cross-sectional view along a vertical plane A-A′ in a figure having a same figure numeral; figures labeled with the suffix “B” represent a vertical cross-sectional view along a vertical plane B-B′ in a figure having a same figure numeral; and figures labeled with the suffix “C” represent a vertical cross-sectional view along a vertical plane C-C′ in a figure having a same figure numeral.

FIGS. 12A-12D are various views of a region of the exemplary structure after formation of a first patterned photoresist layer over a rectangular area according to an embodiment of the present disclosure.

FIGS. 13A-13D are various views of a region of the exemplary structure after performing a first anisotropic etch process according to an embodiment of the present disclosure.

FIGS. 14A-14D are various views of a region of the exemplary structure after formation of a second patterned photoresist layer over a rectangular area according to an embodiment of the present disclosure.

FIGS. 15A-15D are various views of a region of the exemplary structure after performing a second anisotropic etch process according to an embodiment of the present disclosure.

FIGS. 16A-16D are various views of a region of the exemplary structure after formation of a third patterned photoresist layer over a rectangular area according to an embodiment of the present disclosure.

FIGS. 17A-17D are various views of a region of the exemplary structure after performing a third anisotropic etch process according to an embodiment of the present disclosure.

FIGS. 18A-18D are various views of a region of the exemplary structure after formation of a fourth patterned photoresist layer over a rectangular area according to an embodiment of the present disclosure.

FIGS. 19A-19D are various views of a region of the exemplary structure after performing a fourth anisotropic etch process according to an embodiment of the present disclosure.

FIGS. 20A-20D are various views of a region of the exemplary structure after formation of a fifth patterned photoresist layer over a rectangular area according to an embodiment of the present disclosure.

FIGS. 21A-21D are various views of a region of the exemplary structure after performing a fifth anisotropic etch process according to an embodiment of the present disclosure.

FIGS. 22A-22D are various views of a region of the exemplary structure after formation of a sixth patterned photoresist layer over a rectangular area according to an embodiment of the present disclosure.

FIGS. 23A-23D are various views of a region of the exemplary structure after performing a sixth anisotropic etch process according to an embodiment of the present disclosure.

FIG. 24 is a top-down view of a contact well having the first configuration in which numbers represent the depth of a respective horizontally-extending surface segments as measured in units of the uniform vertical pitch.

FIG. 25 is a perspective view of the contact well having the first configuration.

FIG. 26 is a top-down view of a contact well having the second configuration in which numbers represent the depth of a respective horizontally-extending surface segments as measured in units of the uniform vertical pitch.

FIG. 27 is a perspective view of the contact well having the second configuration.

FIG. 28 is a top-down view of the contact well having the third configuration after formation of the contact well.

FIGS. 29A-29D are sequential vertical cross-sectional views of a contact well having a fourth configuration during a subset of processing steps according to an embodiment of the present disclosure.

FIGS. 30A-30C are sequential vertical cross-sectional views of a contact well having a fifth configuration during a subset of processing steps according to an embodiment of the present disclosure.

FIG. 31A is a schematic vertical cross-sectional view of the exemplary structure after formation of a stepped dielectric material portion according to an embodiment of the present disclosure. FIG. 31B is a top-down view of the exemplary structure of FIG. 31A. The hinged vertical cross-sectional plane A-A′ is the cut plane of the vertical cross-sectional view of FIG. 31A.

FIG. 32A is a schematic vertical cross-sectional view of the exemplary structure after formation of memory openings and support openings according to an embodiment of the present disclosure. FIG. 32B is a top-down view of the exemplary structure of FIG. 32A. The hinged vertical cross-sectional plane A-A′ is the cut plane of the vertical cross-sectional view of FIG. 32A.

FIG. 33 is a schematic vertical cross-sectional view of the exemplary structure after formation of sacrificial opening fill structures according to an embodiment of the present disclosure.

FIG. 34 is a vertical cross-sectional view of the exemplary structure after formation of voids in the volumes of the support openings according to an embodiment of the present disclosure.

FIG. 35 is a vertical cross-sectional view of the exemplary structure after formation of support pillar structures according to an embodiment of the present disclosure.

FIG. 36 is a schematic vertical cross-sectional view of the exemplary structure after removal of sacrificial memory opening fill structures according to an embodiment of the present disclosure.

FIGS. 37A-37F are sequential vertical cross-sectional views of a memory opening during formation of a memory opening fill structure according to an embodiment of the present disclosure.

FIG. 38A is a schematic vertical cross-sectional view of the exemplary structure after formation of memory opening fill structures according to an embodiment of the present disclosure. FIG. 38B is a top-down view of the exemplary structure of FIG. 38A. The vertical plane A-A′ is the cut plane of the vertical cross-sectional view of FIG. 38A.

FIG. 39A is a vertical cross-sectional view of the exemplary structure after formation of lateral isolation trenches according to an embodiment of the present disclosure.

FIG. 39B is a top-down view of the exemplary structure of FIG. 39A. The vertical plane A-A′ is the cut plane of the vertical cross-sectional view of FIG. 39A.

FIG. 40A is a see-through top-down view of the exemplary structure of FIGS. 39A and 39B in case the exemplary structure is in a first configuration. FIG. 40B is a see-through top-down view of the exemplary structure of FIGS. 39A and 39B in case the exemplary structure is in a second configuration. FIG. 40C is a see-through top-down view of the exemplary structure of FIGS. 39A and 39B in case the exemplary structure is in a modified first configuration.

FIG. 41 is a vertical cross-sectional view of the exemplary structure after formation of laterally-extending cavities according to an embodiment of the present disclosure.

FIG. 42 is a schematic vertical cross-sectional view of the exemplary structure after formation of electrically conductive layers according to an embodiment of the present disclosure.

FIG. 43A is a vertical cross-sectional view of the exemplary structure after formation of lateral isolation trench fill structures, layer contact via structures, and drain contact via structures according to an embodiment of the present disclosure. FIG. 43B is a top-down view of the exemplary structure of FIG. 43A. The vertical plane A-A′ is the cut plane of the vertical cross-sectional view of FIG. 43A.

FIGS. 44A-44D are various horizontal cross-sectional views of the exemplary structure in the first configuration of FIGS. 43A and 43B at various levels according to embodiments of the present disclosure.

FIGS. 45A-45C are various horizontal cross-sectional views of the exemplary structure in the second configuration of FIGS. 43A and 43B at various levels according to embodiments of the present disclosure.

FIG. 46 is a vertical cross-sectional view of the exemplary structure after formation of a memory die according to an embodiment of the present disclosure.

FIG. 47 is a vertical cross-sectional view of a logic die according to an embodiment of the present disclosure.

FIG. 48 is a vertical cross-sectional view of the exemplary structure after attaching the logic die to the memory die according to an embodiment of the present disclosure.

FIG. 49 is a vertical cross-sectional view of the exemplary structure after removal of the carrier substrate according to an embodiment of the present disclosure.

FIG. 50 is a vertical cross-sectional view of the exemplary structure after formation of a source layer and backside contact structures according to the first or the second embodiments of the present disclosure.

### DETAILED DESCRIPTION

As discussed above, the embodiments of the present disclosure are directed to a method of forming a rectangular array contact well for a three-dimensional memory device, the various aspects of which are described below. Embodiments of the disclosure can be employed to form various structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

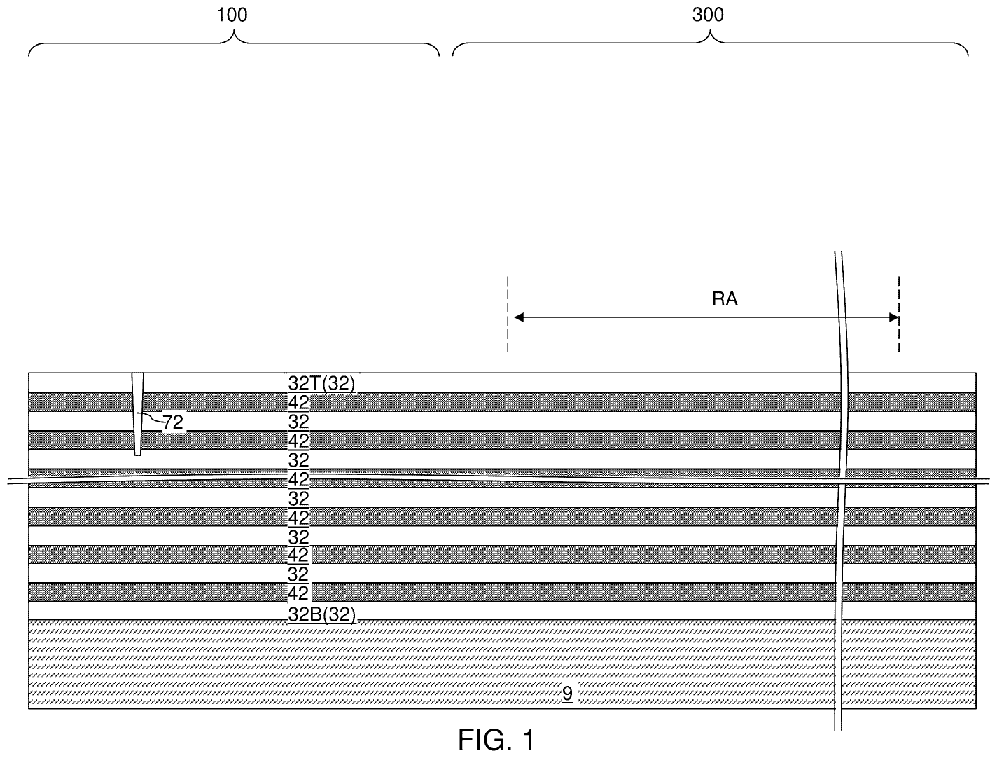

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed. Drain-select-level isolation structures 72 may be formed through a subset of the uppermost sacrificial material layers 42 that will be replaced with drain side select gate electrodes.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

Generally, an alternating stack (32, 42) of insulating layers 32 and spacer material layers (such as sacrificial material layers 42) may be formed over a substrate (such as a carrier substrate 9). The spacer material layers (such as sacrificial material layers 42) are formed, or are subsequently replaced with, electrically conductive layers. Each of the insulating layers 32 has a first thickness and each of the spacer material layers (such as the sacrificial material layers 42) has a second thickness. Thus, the sum of the first thickness and the second thickness is the periodicity of repetition in the alternating stack (32, 42) along the vertical direction corresponds to a height of one step (i.e., step height) to be formed, and is herein referred to as a uniform vertical pitch. Thus, the insulating layers 32 are repeated along the vertical direction with the uniform vertical pitch. Likewise, the spacer material layers (such as the sacrificial material layers 42) are repeated along the vertical direction with the uniform vertical pitch.

According to an aspect of the present disclosure, a rectangular contact area is provided within the area of the contact region 300. The rectangular contact area has a shape of a rectangular area RA in a plan view and further comprises a surrounding area that surrounds the rectangular area RA. The rectangular area RA comprises a periphery including a pair of lengthwise sides laterally extending along a first horizontal direction and a pair of widthwise sides laterally extending along a second horizontal direction in a plan view.

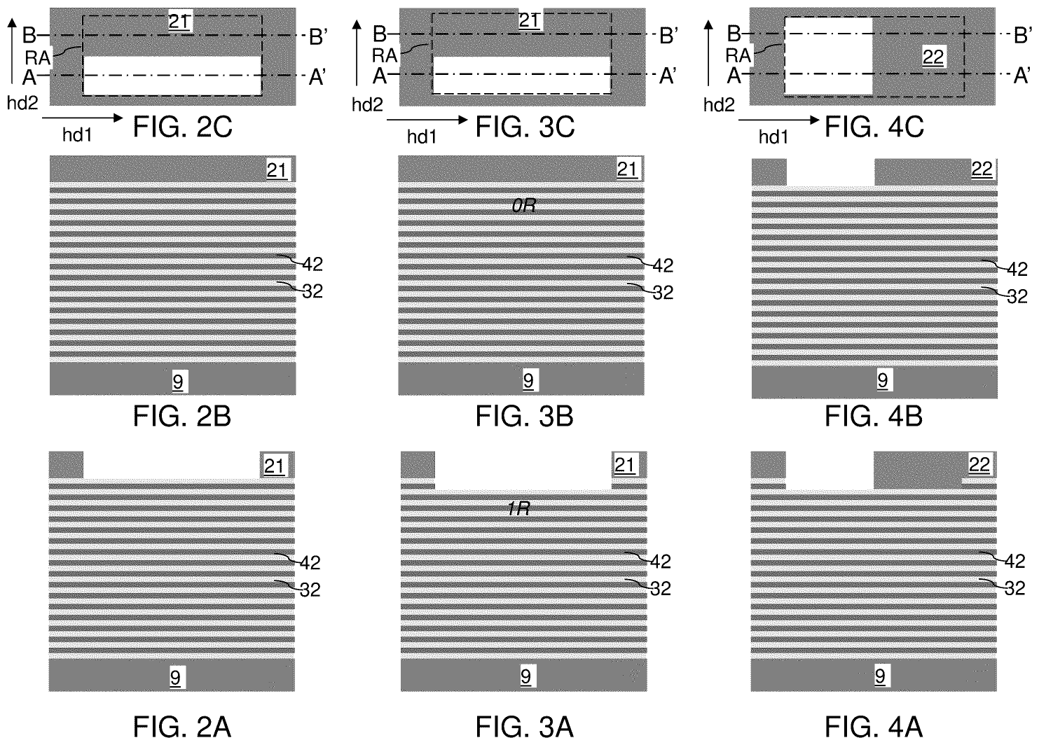

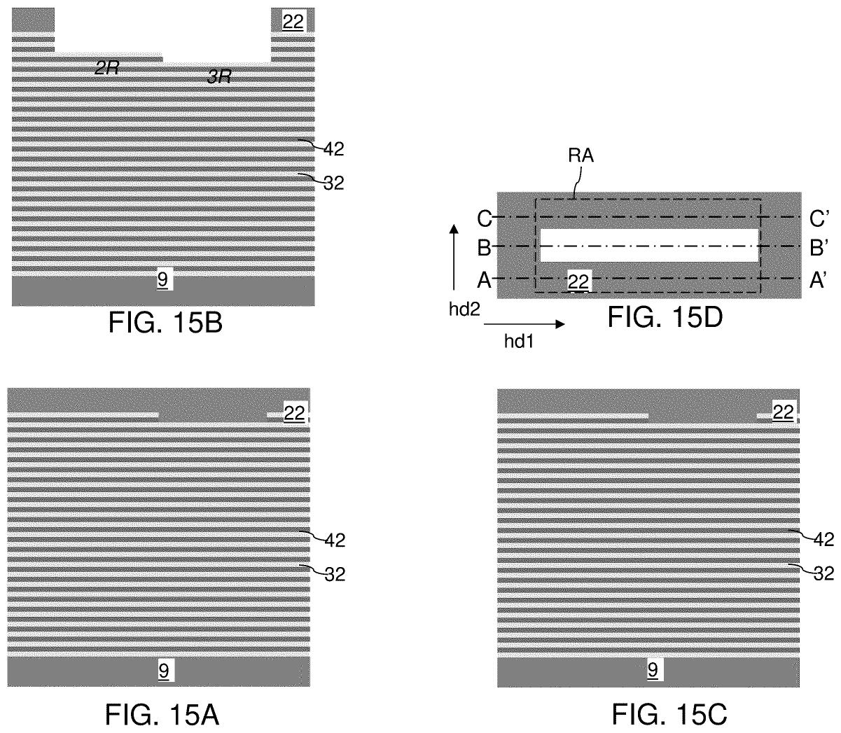

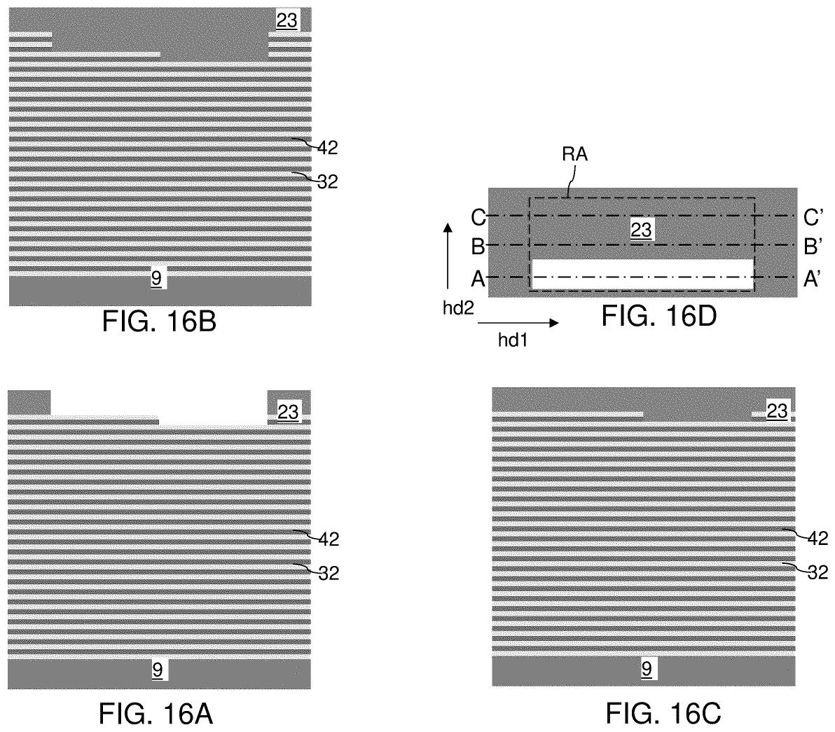

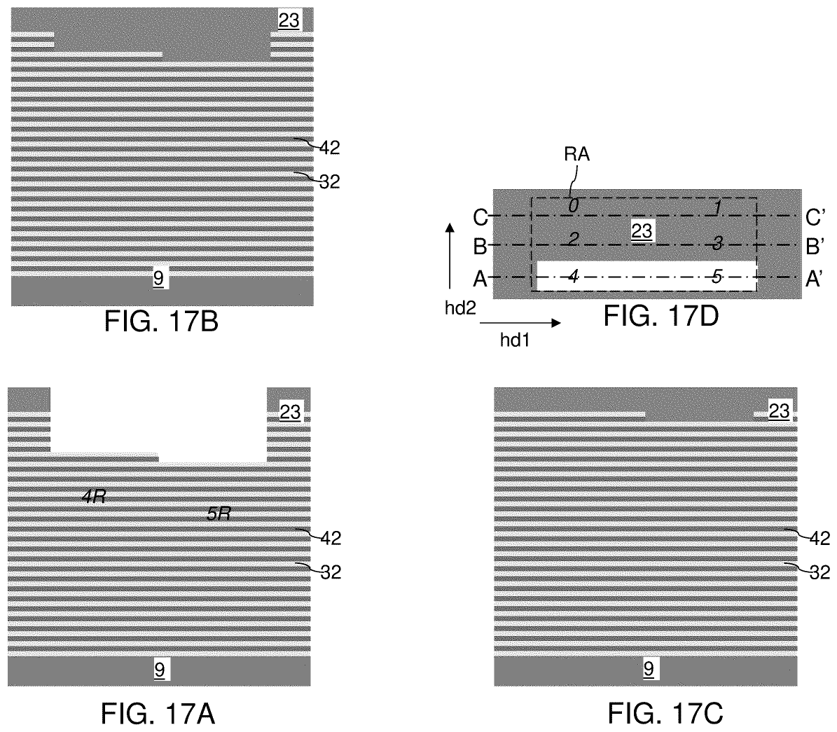

FIGS. 2A-11C illustrate a first sequence of manufacturing processes that may be employed to form a 16 step deep contact well with two rows of steps having a first configuration according to an embodiment of the present disclosure. Each figure is labeled with a combination of figure numeral and a suffix selected from A, B, and C. Within FIGS. 2A-11C, figures labeled with the suffix “C” represent top-down views; figures labeled with the suffix “A” represent a vertical cross-sectional view along a vertical plane A-A′ in a figure having a same figure numeral; and figures labeled with the suffix “B” represent a vertical cross-sectional view along a vertical plane B-B′ in a figure having a same figure numeral. Italic numbers followed by letter “R” represent the depth of a region (i.e., the depth of the recess located over the region) in units of a number of steps (e.g., in units of uniform vertical pitch).

Referring to FIGS. 2A-2C, a first photoresist layer 21 can be applied over the alternating stack (32, 42), and can be lithographically patterned to form a rectangular opening within the rectangular area RA. The rectangular opening within the first photoresist layer 21 may comprise a pair of lengthwise sidewalls that laterally extend along the first horizontal direction hd1, and a pair of widthwise sidewalls that laterally extend along the second horizontal direction hd2. In one embodiment, the widthwise sidewalls of the rectangular opening in the first photoresist layer 21 can be located at segments of the pair of widthwise sides of the rectangular area RA. A lengthwise sidewall of the rectangular opening in the first photoresist layer 21 may extend over the rectangular area RA, and another lengthwise sidewall of the rectangular opening in the photoresist layer 21 may coincide with a lengthwise side of the rectangular area RA.

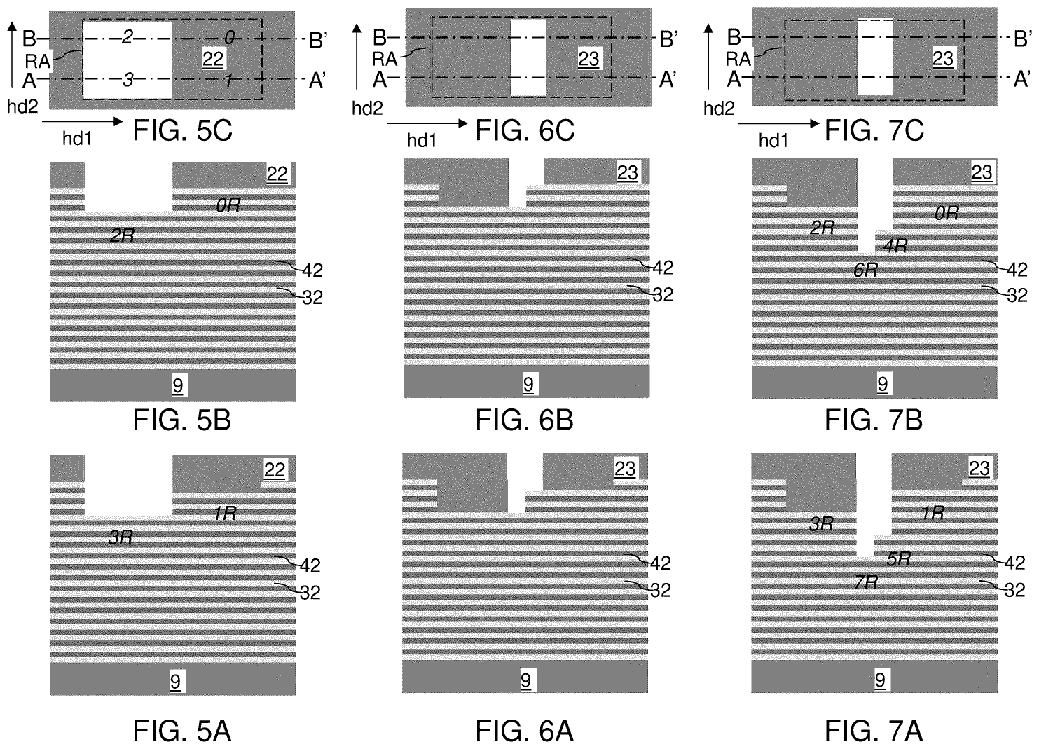

Referring to FIGS. 3A-3C, an initial anisotropic etch process can be performed to etch unmasked portions of the alternating stack (32, 42) to form a step in the alternating stack. In one embodiment, the vertical recess distance of the initial anisotropic etch process may be the same as the uniform vertical pitch, i.e., the step height which is the sum of the first thickness of the etched topmost insulating layer 32 and the second thickness of the etched topmost sacrificial material layer 42. In one embodiment, the initial anisotropic etch process may comprise a first-type anisotropic etch step that etches the first material of a topmost insulating layer 32 selective to the second material of the topmost sacrificial material layer 42, and a second-type anisotropic etch step that etches the second material of the topmost sacrificial material layer 42 selective to the first material of an underlying insulating layer 32, i.e., the insulating layer 32 that is the second from the top among the insulating layers 32. A lengthwise step (having the step height which equals to the uniform vertical pitch) that laterally extends along the first horizontal direction hd1 (i.e., the lengthwise direction of the rectangular area RA) can be formed within the rectangular area RA. In one embodiment, the lengthwise step may divide the rectangular area RA into two areas of the same size or of similar sizes.

The lengthwise step laterally extends along the first horizontal direction hd1 between the pair of widthwise sides of the rectangular area RA of the alternating stack (32, 42). Each horizontal surface segment within the rectangular area RA of the alternating stack (32, 42) is formed at 2 different levels. The first photoresist layer 21 can be subsequently removed, for example, by ashing.

Generally, the lengthwise step may be formed by applying a photoresist layer (such as the first photoresist layer 21) over the alternating stack (32, 42); forming an elongated rectangular opening in the photoresist layer to provide a sidewall that laterally extends along the first horizontal direction hd1 over the rectangular area RA; and recessing portions of the alternating stack (32, 42) located within the respective elongated opening by a recess etch distance. The recess etch distance employed to form the lengthwise step is a product of a positive integer (which may be 1, for example) and the sum of the first thickness and the second thickness. In one embodiment, the photoresist layer may have a pair of widthwise sidewalls that coincide with the pair of widthwise sides of the rectangular area RA in a plan view (such as a top-down view).

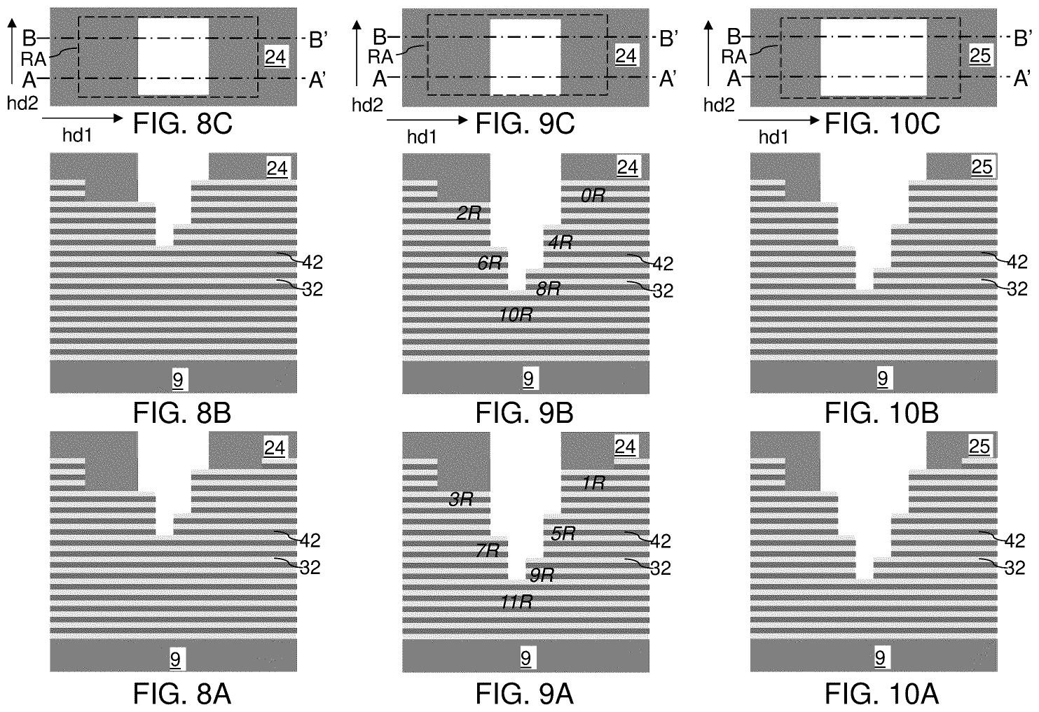

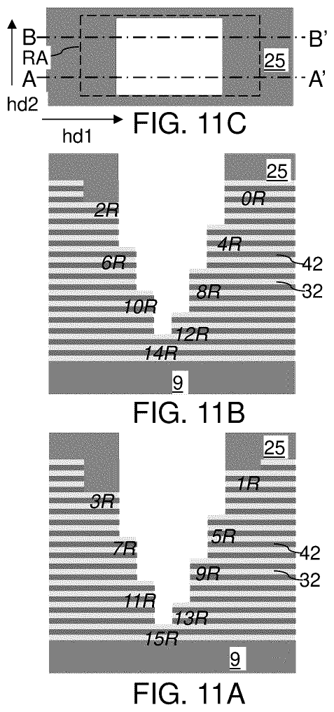

Referring collectively to FIGS. 4A-5C, a first instance of a stepped surface formation processing sequence can be subsequently performed.

Referring to FIGS. 4A-4C, the first instance of the stepped surface formation processing sequence may comprise a first masking process in which a second photoresist layer 22 is applied over the alternating stack (32, 42) and is lithographically patterned to partially mask the rectangular area RA and completely mask the surrounding area. A sidewall of the second photoresist layer 22 extends over the rectangular area RA along the second horizontal direction hd2. In one embodiment, a rectangular opening may be formed within the second photoresist layer 22 such that a sidewall of the rectangular opening is the sidewall that extends over the rectangular area RA, and additional sidewalls of the rectangular opening coincide with segments of the pair of lengthwise sides of the rectangular area RA and an entirety of a widthwise side of the rectangular area RA in the plan view. The area of the rectangular opening in the second photoresist layer 22 may be about one half of the total area of the rectangular area RA.

Referring to FIGS. 5A-5C, a first anisotropic etch process can be performed, which is one of the processing steps of the first instance of the stepped surface formation processing sequence. The first anisotropic etch process etches portions of the alternating stack (32, 42) that are not masked by the second photoresist layer 22 by a first recess etch depth. The first recess etch depth may be a product of a first positive integer (which may be 1) and the total number of levels of horizontal surface segments in the rectangular area RA after formation of the lengthwise step (which is 2 in this case), and the etched step height (which is the uniform vertical pitch which equals the sum of the first thickness and the second thickness). Thus, the lowest recessed region of the alternating stack is recessed by 3 steps (i.e., one lengthwise and two widthwise steps in the region 3R shown in FIG. 5A). Other regions of the alternating stack are recessed by zero steps and two steps (i.e., regions 0R and 2R shown in FIG. 5B) and by one step (i.e., region 1R shown in FIG. 5A).

In one embodiment, the insulating layers 32 comprise a first material such as silicon oxide, the spacer material layers (such as sacrificial material layers 42) comprise a second material such as silicon nitride, and the first anisotropic etch process comprises an alternating sequence of a first-type anisotropic etch step that etches the first material selective to the second material and a second-type anisotropic etch step that etches the second material selective to the first material.

The first instance of the stepped surface formation processing sequence further comprises a photoresist removal process, which removes the second photoresist layer 22, for example, by ashing. A widthwise step is formed within the rectangular area RA.

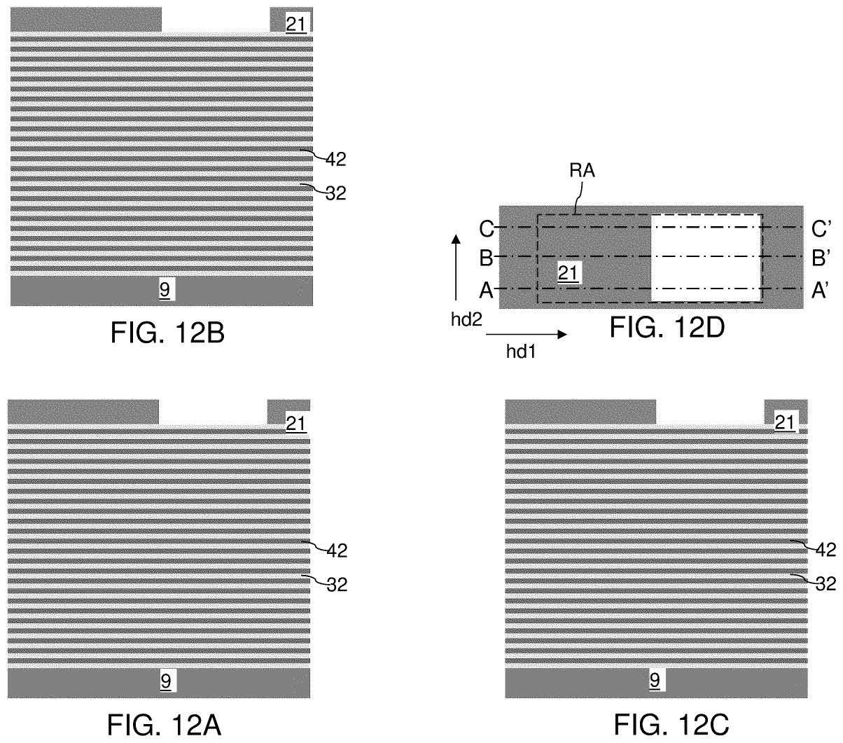

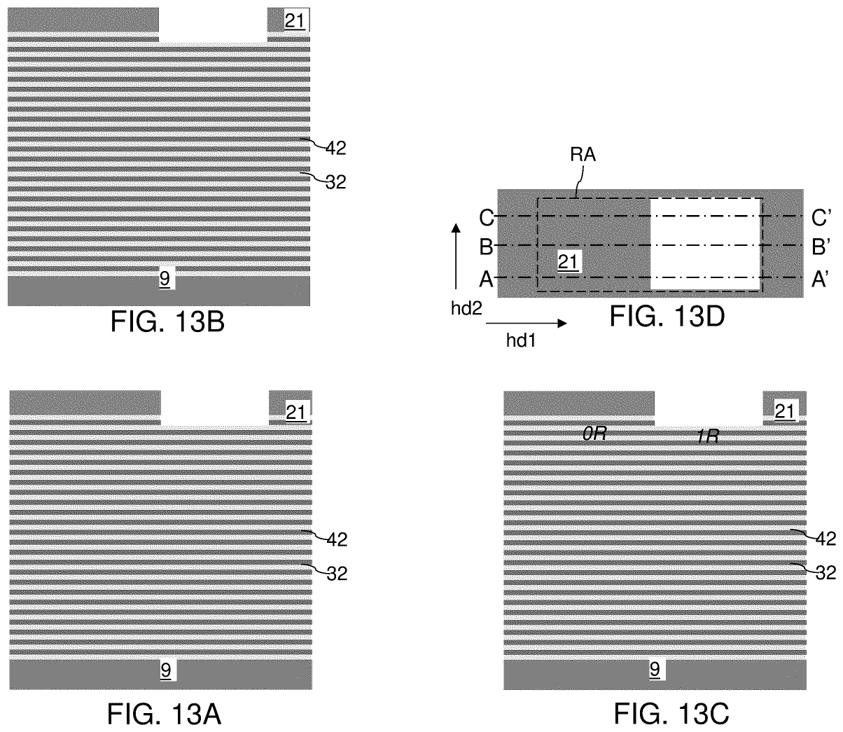

Referring collectively to FIGS. 6A-7C, a second instance of the stepped surface formation processing sequence can be performed.

Referring to FIGS. 6A-6C, the second instance of the stepped surface formation processing sequence may comprise a second masking process in which a third photoresist layer 23 is applied over the alternating stack (32, 42) and is lithographically patterned to partially mask the rectangular area RA and completely mask the surrounding area. A sidewall of the third photoresist layer 23 extends over the rectangular area RA along the second horizontal direction hd2. In one embodiment, a rectangular opening may be formed within the third photoresist layer 23 such that a sidewall of the rectangular opening is the sidewall that extends over the rectangular area RA, and additional sidewalls of the rectangular opening coincide with segments of the pair of lengthwise sides of the rectangular area RA and an entirety of a widthwise side of the rectangular area RA in the plan view.

Referring to FIGS. 7A-7C, a second anisotropic etch process can be performed, which is one of the processing steps of the second instance of the stepped surface formation processing sequence. The second anisotropic etch process etches portions of the alternating stack (32, 42) that are not masked by the third photoresist layer 23 by a second recess etch depth. The second recess etch depth may be a product of a second positive integer (which may be 2), the total number of levels of horizontal surface segments in the rectangular area RA after formation of the lengthwise step (which is 2 in this case), and the step height (i.e., the uniform vertical pitch).

The second instance of the stepped surface formation processing sequence further comprises a photoresist removal process, which removes the third photoresist layer 23, for example, by ashing. Additional widthwise steps are formed within the rectangular area RA.

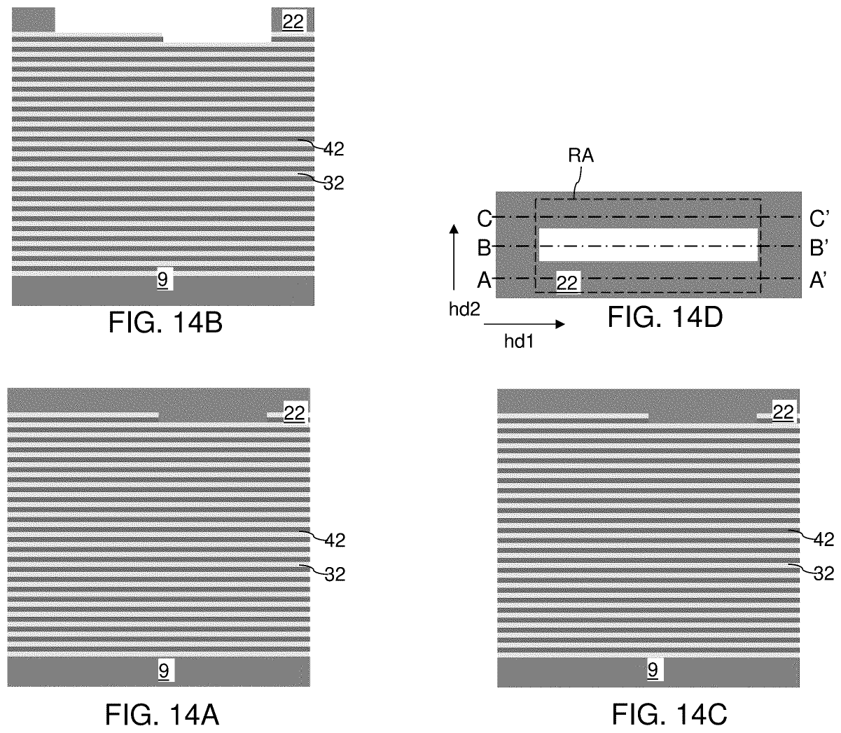

Referring collectively to FIGS. 8A-11C, additional instances of the stepped surface formation processing sequence can be performed employing additional photoresist layers (24, 25) and additional anisotropic etch processes. The patterns of the openings in the additional photoresist layers (24, 25) and the recess depths of the additional anisotropic etch processes can be selected such that a two-dimensional array, such as a 2×N array, of rectangular horizontally-extending surface segments is formed within the rectangular area RA.

Referring collectively to FIGS. 4A-11C, a plurality of widthwise steps laterally extending along the second horizontal direction hd2 can be formed between the pair of lengthwise sides of the rectangular area RA of the alternating stack (32, 42) by performing multiple instances of the stepped surface formation processing sequence. Each instance of the stepped surface formation processing sequence comprises a respective masking process in which a respective photoresist layer is applied over the alternating stack (32, 42) and is lithographically patterned to partially mask the rectangular area RA and completely mask the surrounding area. The respective masking process provides a respective sidewall of the respective photoresist layer that extends over the rectangular area RA along the second horizontal direction hd2. Each instance of the stepped surface formation processing sequence further includes a respective anisotropic etch process that etches respective portions of the alternating stack (32, 42) that are not masked by the respective photoresist layer by a respective recess etch depth. In addition, each instance of the stepped surface formation processing sequence comprises a respective photoresist removal process that removes the respective photoresist layer, the respective recess etch depth being a product of a respective positive integer, the total number of levels of horizontal surface segments in the rectangular area RA after formation of the lengthwise step (which is 2 in this case but may be greater in general), and a sum of the first thickness and the second thickness.

In one embodiment, each photoresist layer (21, 22, 23, 24, 25) is patterned only once, and is used as an etch mask only during formation of a respective step prior to being removed. Thus, in this embodiment, the photoresist layer is not trimmed (i.e., not etched) back to reduce its length, width and height, and is not used as an etch mask to etch two different steps in two separate etching steps.

In one embodiment, the respective positive integer is 1 for at least one instance among the instances of the stepped surface formation processing sequence; and the respective positive integer is 2 for at least another instance among the instances of the stepped surface formation processing sequence. In one embodiment, the respective photoresist layer comprises at least one rectangular opening such that the respective sidewall of the respective photoresist layer comprises a sidewall of the at least one rectangular opening. In one embodiment, each of the at least one rectangular opening of the respective photoresist layer comprises additional sidewalls that coincides with segments of the pair of lengthwise sides of the rectangular area RA in the plan view.

In one embodiment, the insulating layers 32 comprise a first material; the spacer material layers (such as sacrificial material layers 42) comprise a second material; and each anisotropic etch process within the multiple instances of the stepped surface formation processing sequence comprises an alternating sequence of a first-type anisotropic etch step that etches the first material selective to the second material and a second-type anisotropic etch step that etches the second material selective to the first material.

In the first configuration of the exemplary structure illustrated in FIGS. 2A-11C, a 2×8 array of rectangular horizontally-extending surface segments located at 16 different levels (i.e., a 16 step well) is formed. Generally, an M×N array of rectangular horizontally-extending surface segments can be formed, in which M is an integer greater than 1, and N is an integer greater than M.

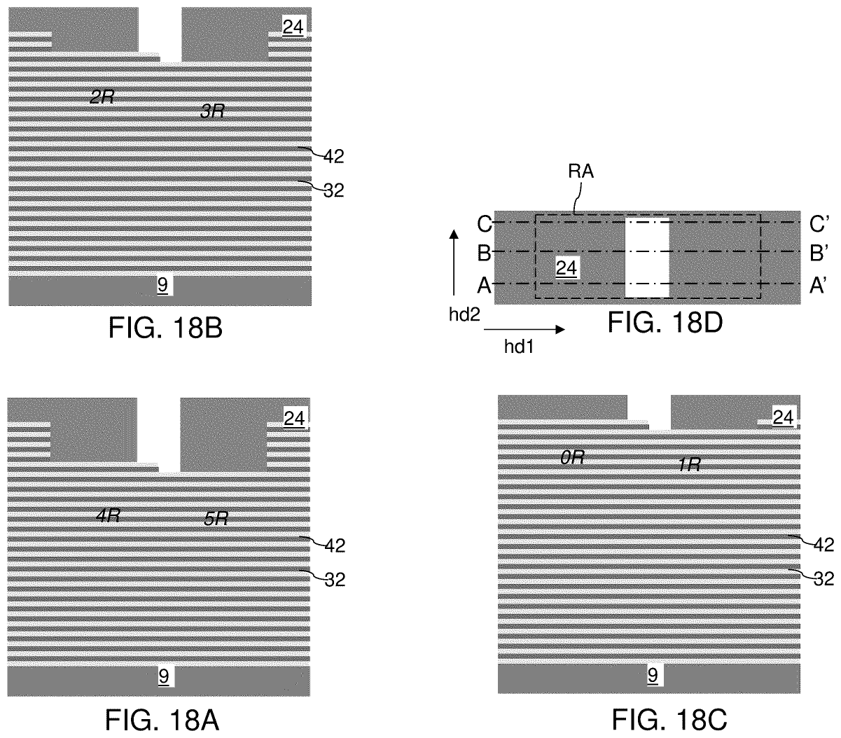

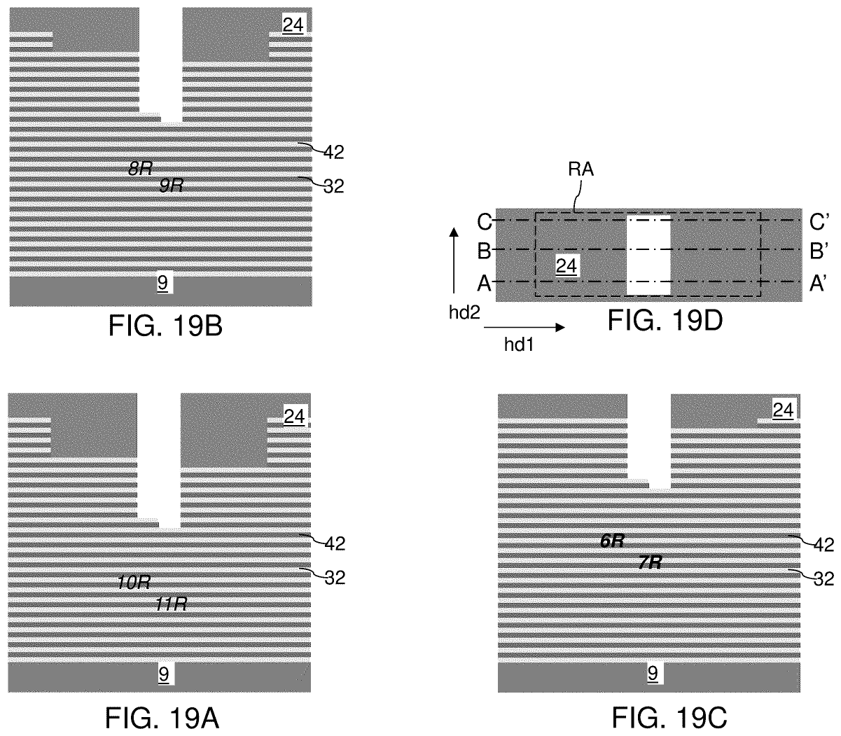

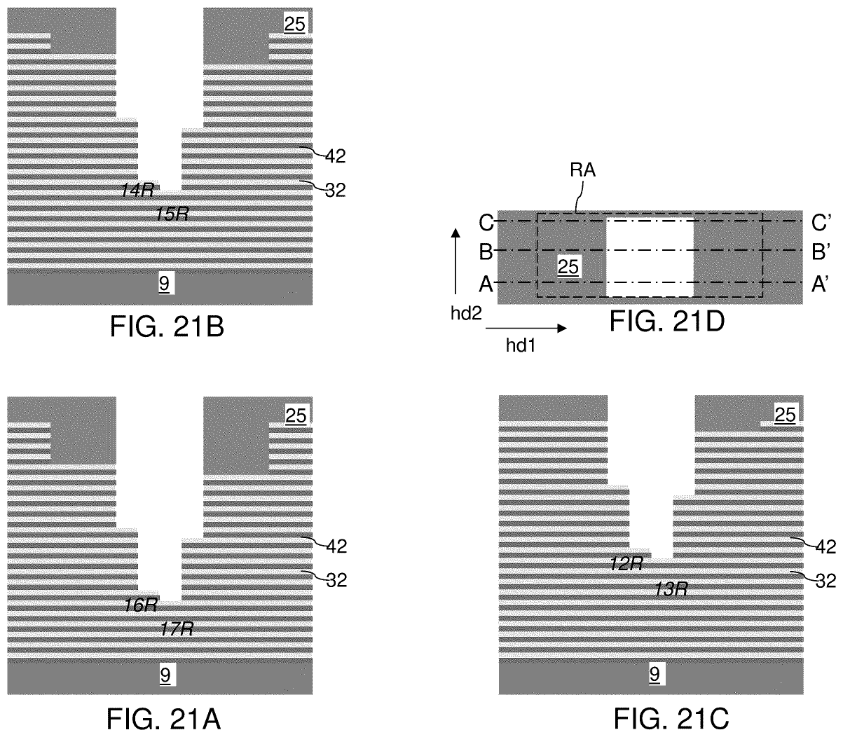

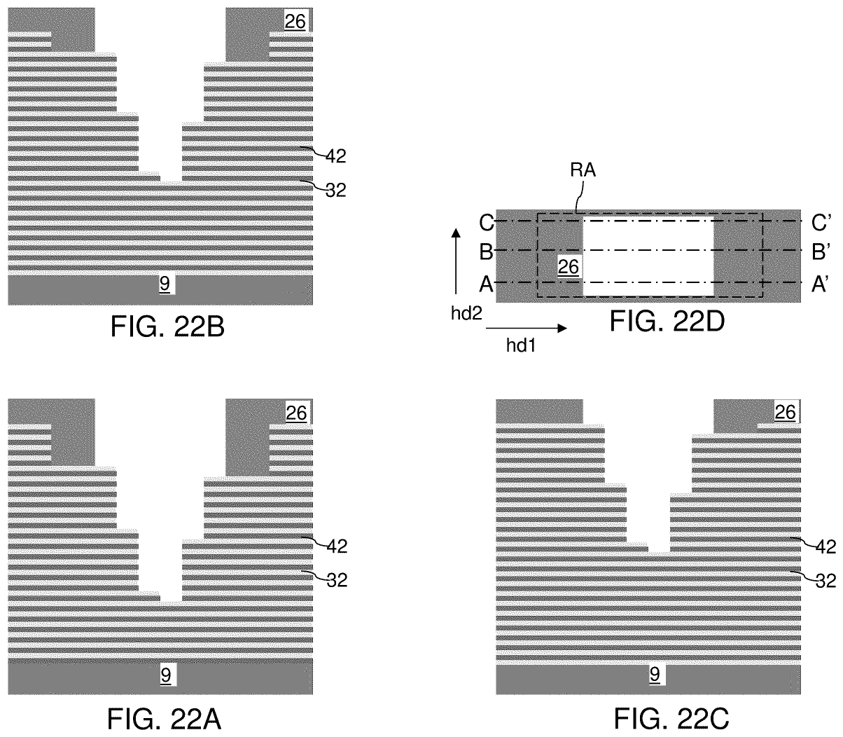

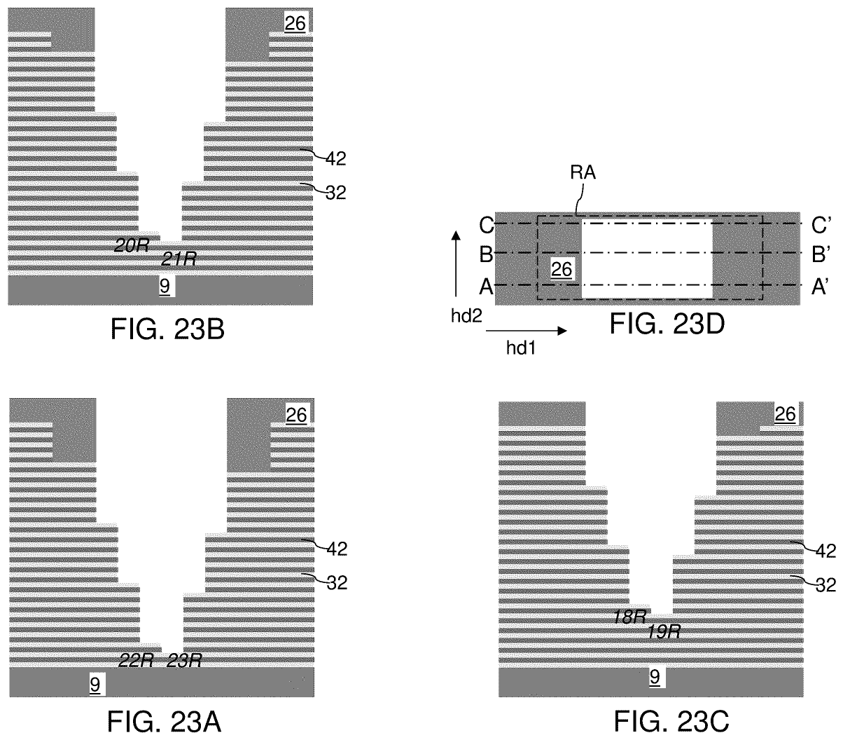

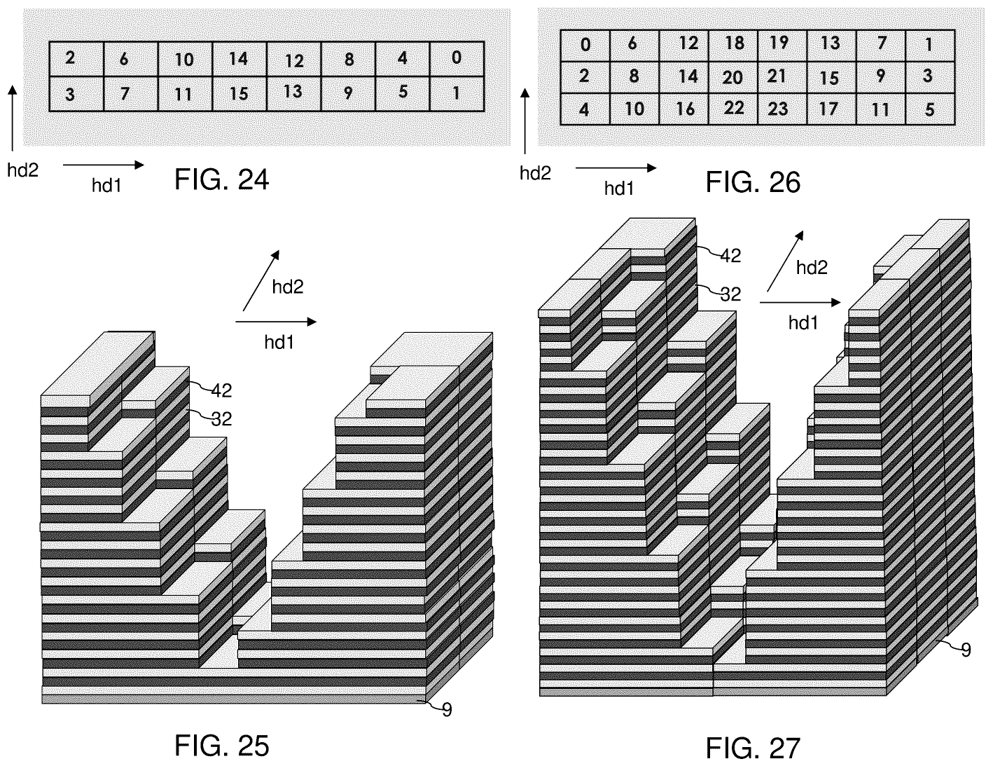

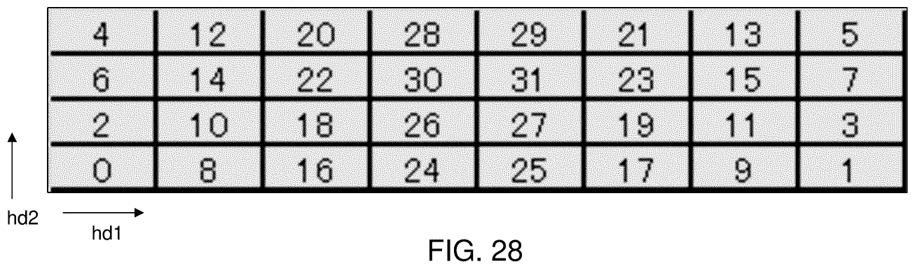

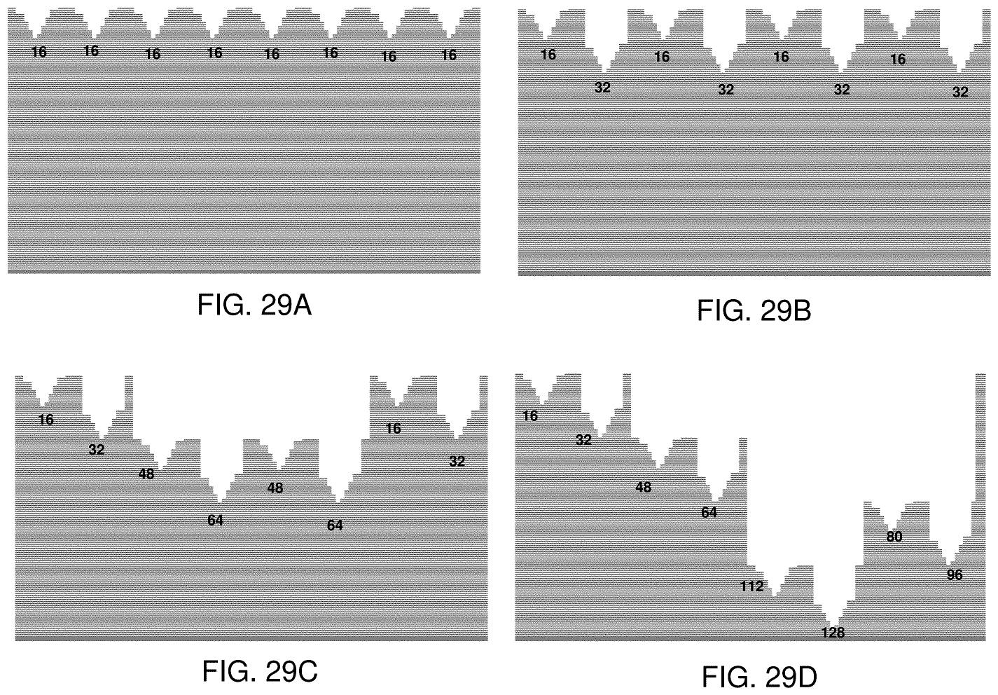

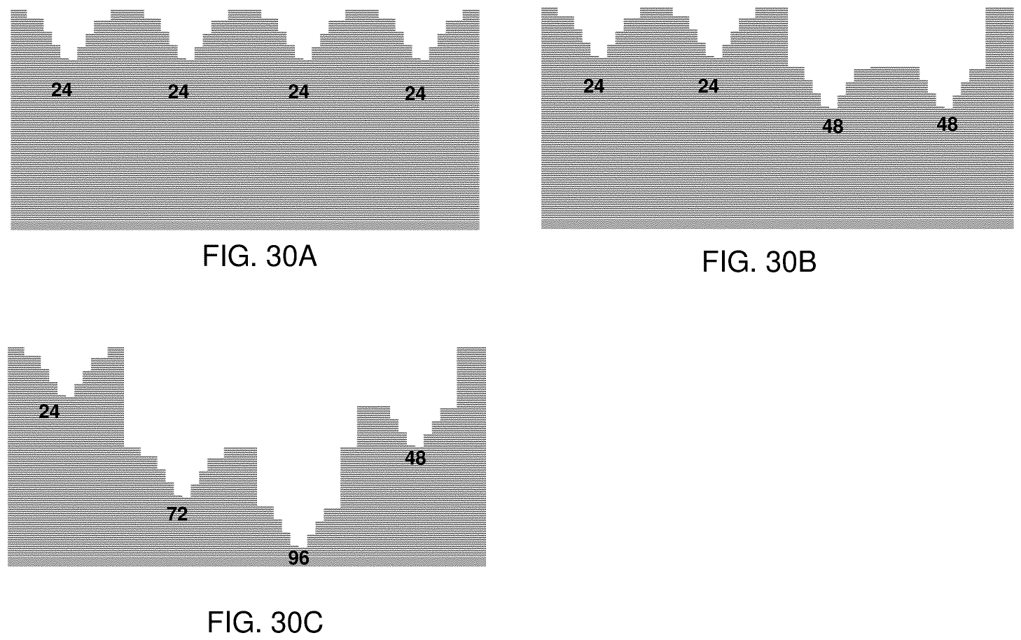

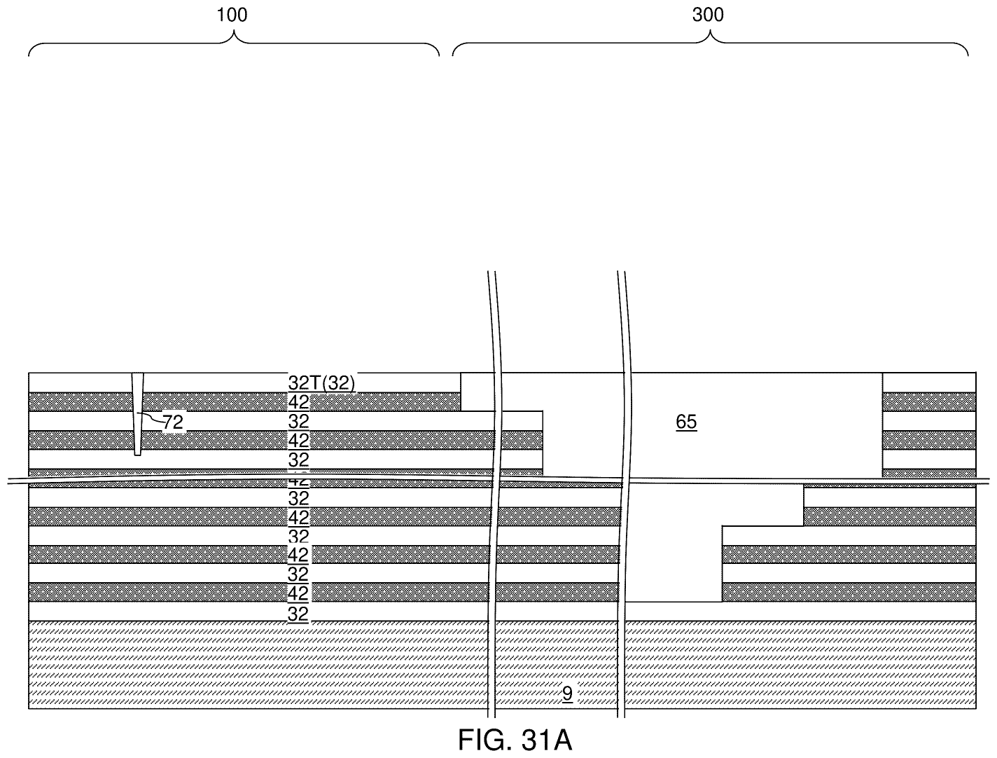

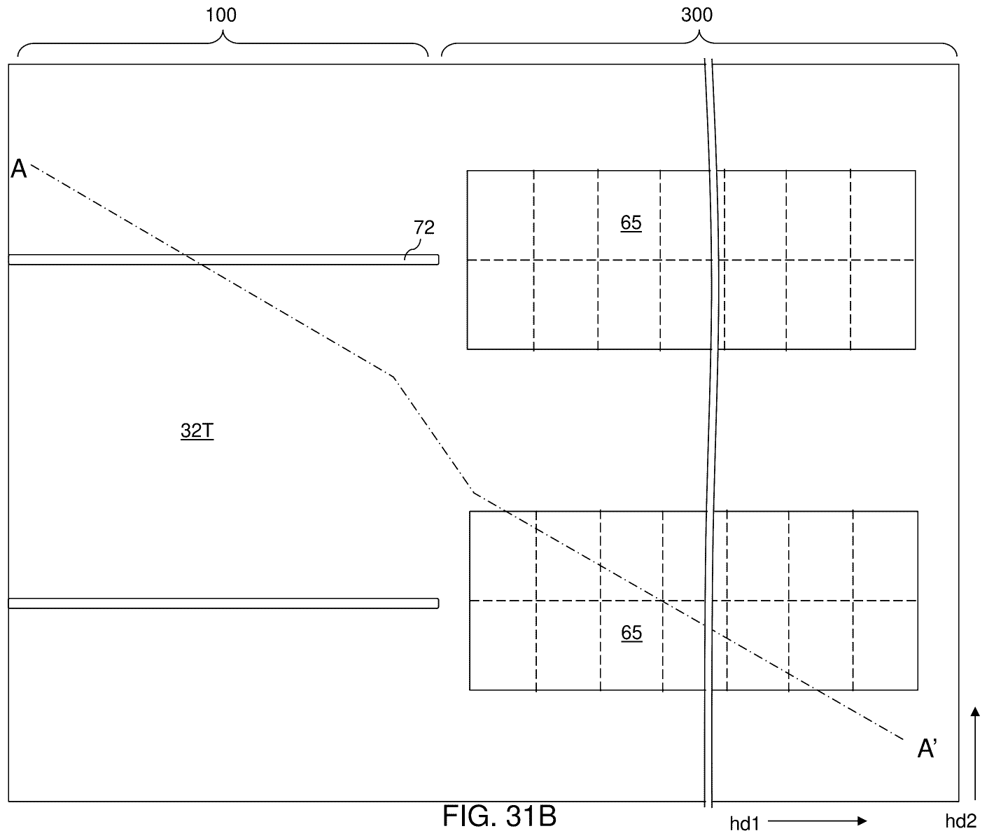

FIGS. 12A-23D illustrate a second sequence of manufacturing processes that may be employed to form a 24 step deep contact well with three rows of steps having a second configuration according to an embodiment of the present disclosure. Each figure is labeled with a combination of figure numeral and a suffix selected from A, B, C, and D. Within FIGS. 12A-23D, figures labeled with the suffix “D” represent top-down views; figures labeled with the suffix “A” represent a vertical cross-sectional view along a vertical plane A-A′ in a figure having a same figure numeral; figures labeled with the suffix “B” represent a vertical cross-sectional view along a vertical plane B-B′ in a figure having a same figure numeral; and figures labeled with the suffix “C” represent a vertical cross-sectional view along a vertical plane C-C′ in a figure having a same figure numeral.

Generally, lengthwise steps that are parallel to the pair of lengthwise sides of the rectangular area RA and widthwise steps that are parallel to the pair of widthwise sides of the rectangular area RA may be formed in any order. Further, the total number of levels of horizontal surface segments in the rectangular area RA after formation of the lengthwise steps may be any integer greater than 1. Thus, while the embodiment described with reference to FIGS. 2A-11C forms 2 levels of horizontal surface segments (i.e., two rows of steps) by forming a single lengthwise step extending along the first horizontal direction hd1, 2 or more lengthwise steps (e.g., three or more rows of steps) may be formed within the rectangular area RA in general.

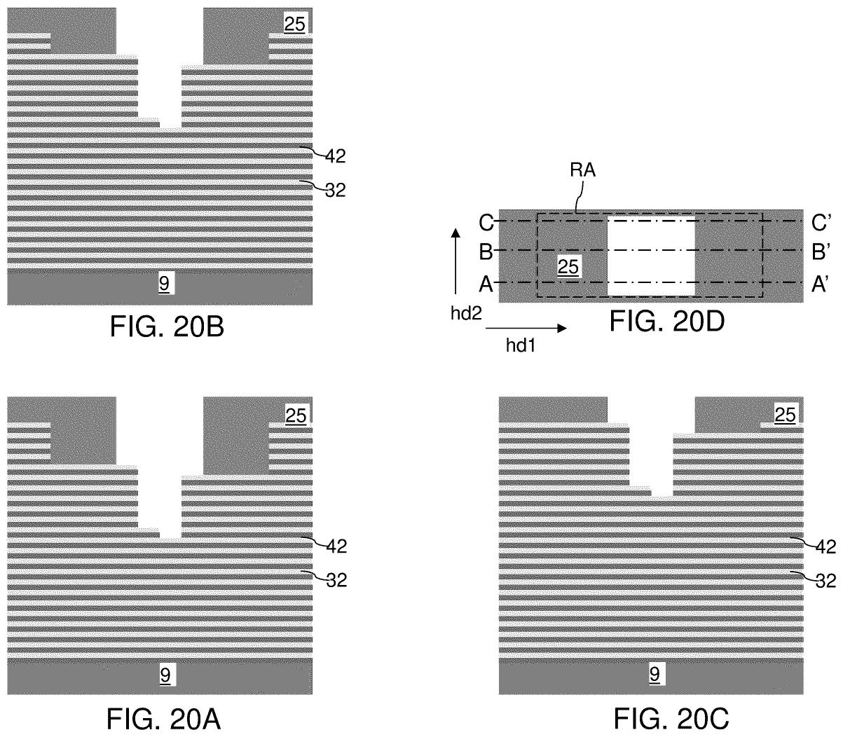

In the second configuration of the exemplary structure illustrated in FIGS. 12A-23D, a total of six photoresist layers (21, 22, 23, 24, 25, 26) and a total of six anisotropic etch processes are employed. Two lengthwise steps are formed within the rectangular area RA at the processing steps described with reference to FIGS. 14A-17D such that 3 levels of horizontal surface segments are formed by forming two lengthwise steps extending along the first horizontal direction hd1. The total number of levels of horizontal surface segments that are present in a single vertical cross-sectional view along the second horizontal direction hd2 after formation of all of the lengthwise step(s) is hereafter referred to as M, which is an integer greater than 1.

Widthwise steps are formed within the rectangular area RA at the processing steps described with reference to FIGS. 12A-13D and 18A-23D.

Referring collectively to FIGS. 12A-23D, at least one lengthwise step laterally extending along the first horizontal direction hd1 is formed between the pair of widthwise sides of the rectangular area RA of the alternating stack (32, 42). Each horizontal surface segment within the rectangular area RA of the alternating stack (32, 42) is formed at M different levels. In one embodiment, M may be an integer in a range from 2 to 6. In one embodiment, M may have a value selected from 2 and 3.

In one embodiment, each of the at least one lengthwise step may be formed by: applying a respective photoresist layer over the alternating stack (32, 42); forming a respective elongated rectangular opening in the respective photoresist layer to provide a sidewall that laterally extends along the first horizontal direction hd1 over the rectangular area RA; and recessing portions of the alternating stack (32, 42) located within the respective elongated opening by a respective recess etch distance. In one embodiment, each recess etch distance employed to form the at least one lengthwise step is a product of a respective positive integer and the sum of the first thickness and the second thickness. In one embodiment, each photoresist layer has a pair of widthwise sidewalls that coincide with the pair of widthwise sides of the rectangular area RA in the plan view.

Further, referring collectively to FIGS. 12A-23D, a plurality of widthwise steps can be formed, which laterally extends along the second horizontal direction hd2 between the pair of lengthwise sides of the rectangular area RA of the alternating stack (32, 42). The plurality of widthwise steps can be formed by performing multiple instances of a stepped surface formation processing sequence. In one embodiment, each instance of the stepped surface formation processing sequence comprises a respective masking process in which a respective photoresist layer is applied over the alternating stack (32, 42) and is lithographically patterned to partially mask the rectangular area RA and completely mask the surrounding area. A respective sidewall of the respective photoresist layer extends over the rectangular area RA along the second horizontal direction hd2. Each instance of the stepped surface formation processing sequence comprises a respective anisotropic etch process that etches respective portions of the alternating stack (32, 42) that are not masked by the respective photoresist layer by a respective recess etch depth. Further, each instance of the stepped surface formation processing sequence comprises a respective photoresist removal process that removes the respective photoresist layer. The respective recess etch depth may be a product of a respective positive integer, the integer M, and step height which equals to the sum of the first thickness and the second thickness (i.e., the uniform vertical pitch).

In one embodiment, the respective positive integer is 1 for at least one instance among the instances of the stepped surface formation processing sequence; and the respective positive integer is 2 for at least another instance among the instances of the stepped surface formation processing sequence. In some embodiment, the respective positive integer may be 2K, in which K is a non-negative integer. For example, K may have a value such as 0, 1, 2, 3, 4, 5, 6, 7, etc.

In one embodiment, the respective photoresist layer comprises at least one rectangular opening such that the respective sidewall of the respective photoresist layer comprises a sidewall of the at least one rectangular opening. In one embodiment, each of the at least one rectangular opening of the respective photoresist layer comprises additional sidewalls that coincides with segments of the pair of lengthwise sides of the rectangular area RA in the plan view.

In one embodiment, the insulating layers 32 comprise a first material; the spacer material layers (such as sacrificial material layers 42) comprise a second material; and each anisotropic etch process within the multiple instances of the stepped surface formation processing sequence comprises an alternating sequence of a first-type anisotropic etch step that etches the first material selective to the second material and a second-type anisotropic etch step that etches the second material selective to the first material.

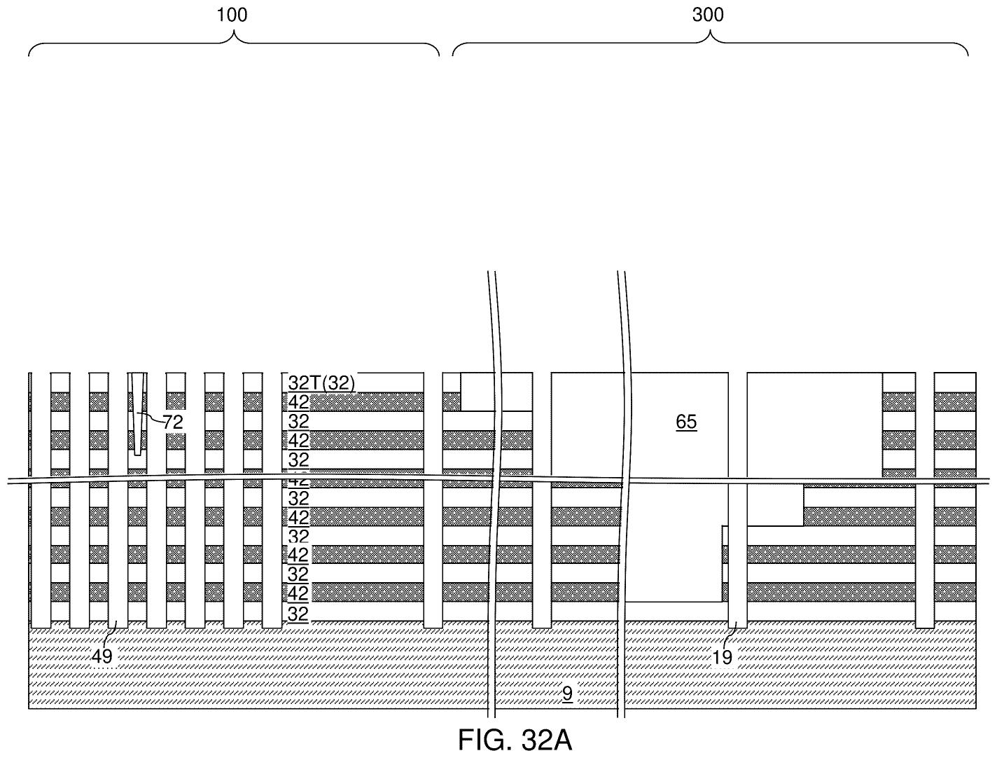

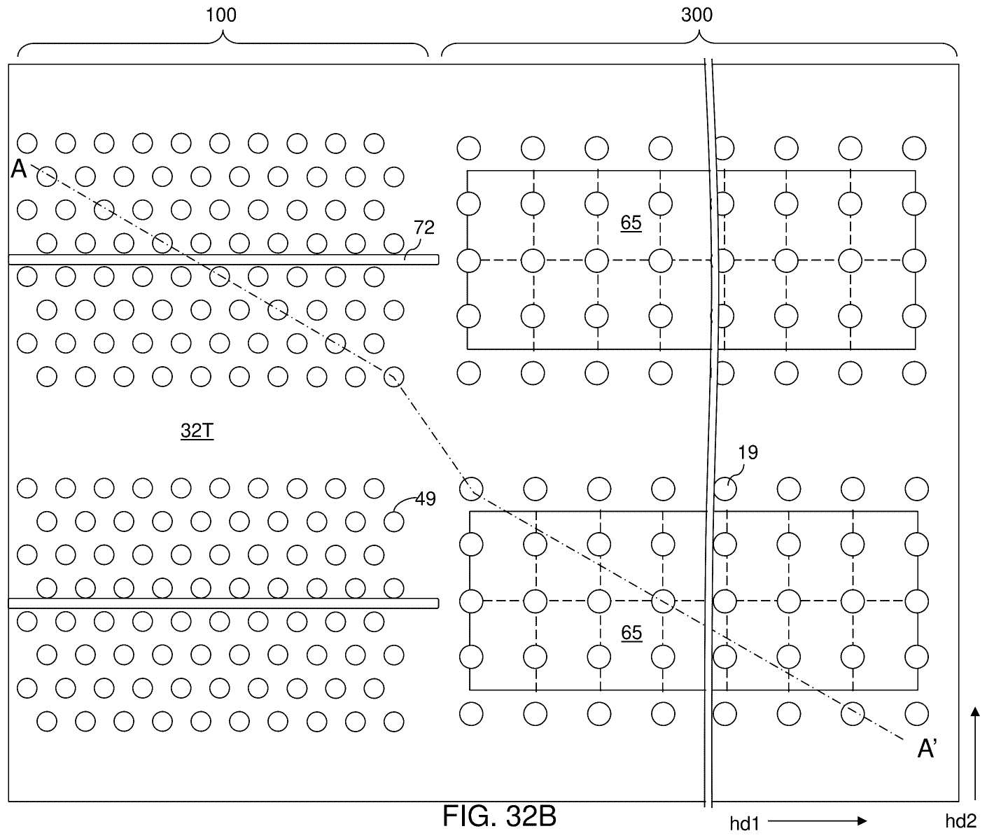

FIG. 24 is a top-down view of a two row, 16 step contact well having the first configuration in which numbers represent the depth of a respective horizontally-extending surface segments as measured in units of the step height (i.e., the uniform vertical pitch). FIG. 25 is a perspective view of the contact well having the first configuration. The 8 steps in each row are offset from each other along the first horizontal (e.g., word line) direction hd1, and the two rows are offset from each other along the second horizontal (e.g., bit line) direction hd2, to provide a total of 16 steps per contact well.

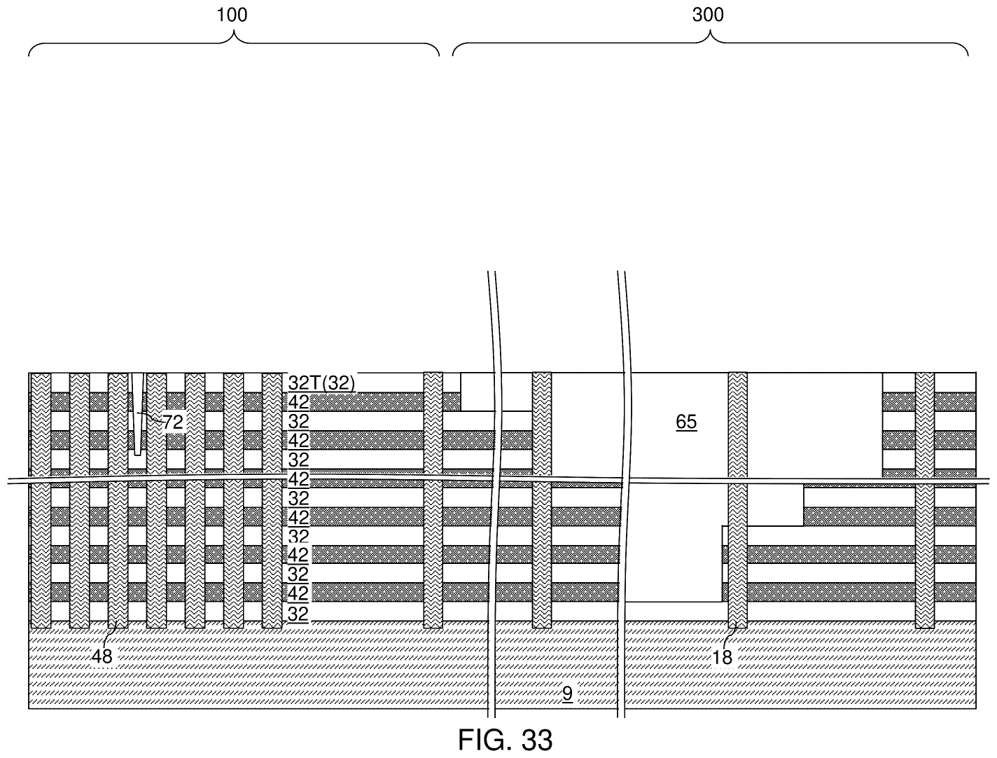

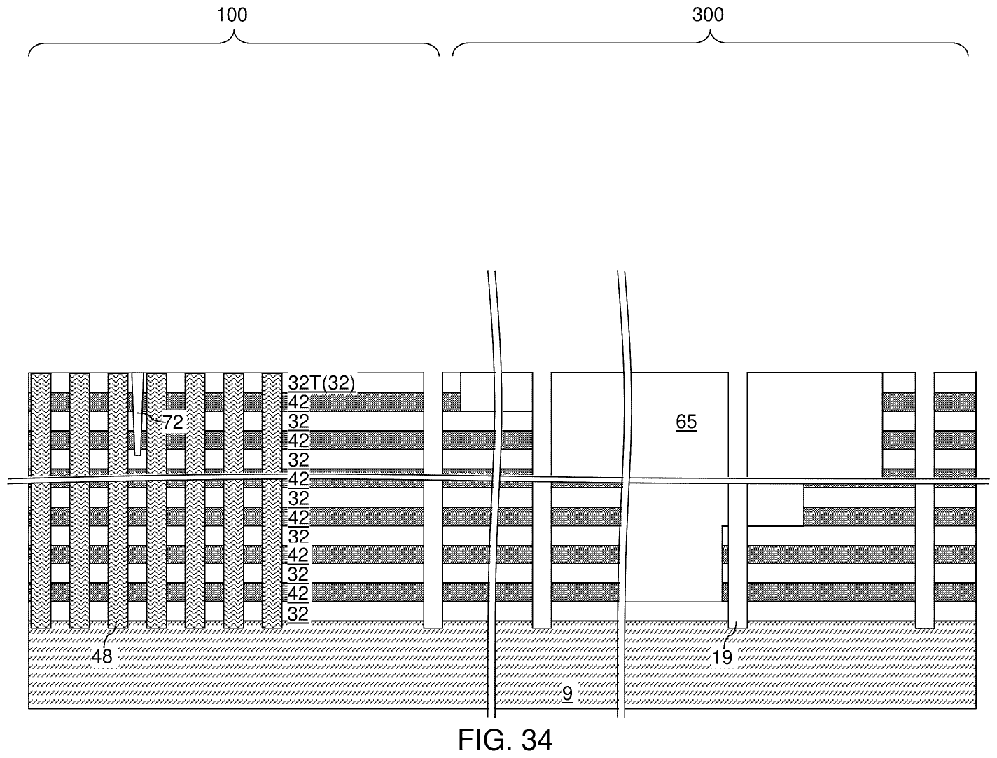

FIG. 26 is a top-down view of a three row, 24 step contact well having the second configuration in which numbers represent the depth of a respective horizontally-extending surface segments as measured in units of the step height (i.e., the uniform vertical pitch). FIG. 27 is a perspective view of the contact well having the first configuration. The 8 steps in each row are offset from each other along the first horizontal (e.g., word line) direction hd1, and the three rows are offset from each other along the second horizontal (e.g., bit line) direction hd2, to provide a total of 24 steps per contact well.

Referring collectively to FIGS. 24-27, a contact well can be formed within the rectangular area RA through formation of the at least one lengthwise step and formation of the plurality of widthwise steps. Peripheral sidewalls of the contact well are formed at the pair of lengthwise sides and at the pair of widthwise sides of the rectangular area RA in the plan view.

In some embodiments, a vertical cross-sectional profile of the contact well along the first horizontal direction hd1 comprises: a descending staircase profile that extends along the first horizontal direction hd1 from a first sidewall of the contact well located at one of the pair of widthwise sides of the rectangular area RA to a bottommost horizontal surface segment of the descending staircase profile; and an ascending staircase profile that extends along the first horizontal direction hd1 from the bottommost horizontal surface segment of the ascending staircase profile to a second sidewall of the contact well located at another of the pair of widthwise sides of the rectangular area RA. In one embodiment, the bottommost horizontal surface segment of the ascending staircase profile may be the same surface segment as the bottommost horizontal surface segment of the descending staircase profile.

In one embodiment, the contact well comprises a total of M×N array of rectangular horizontal surface segments that are vertically offset from each other. N (i.e., number of steps per row) is an integer greater than M (i.e., the number of rows). FIGS. 24 and 25 illustrate an example in which M is 2, and N is 8. FIGS. 26 and 27 illustrate an example in which M is 3, and N is 8.

In one embodiment, the contact well comprises M rows of stepped surfaces, each row of stepped surfaces comprising a respective set of N rectangular horizontal surface segments (i.e., steps) that are arranged along the first horizontal direction hd1. Each row of stepped surfaces of the M rows of stepped surfaces is laterally offset relative any other row of stepped surfaces of the M rows of stepped surfaces by a respective uniform vertical offset distance that is invariant along the first horizontal direction hd1. The respective uniform vertical offset distance can be an integer multiple of the sum of the first thickness and the second thickness, i.e., an integer multiple of the step heights (i.e., of the uniform vertical pitch). In FIGS. 24 and 25, the uniform vertical offset distance is the step height. In FIGS. 26 and 27, each uniform vertical offset distance is twice the step height.

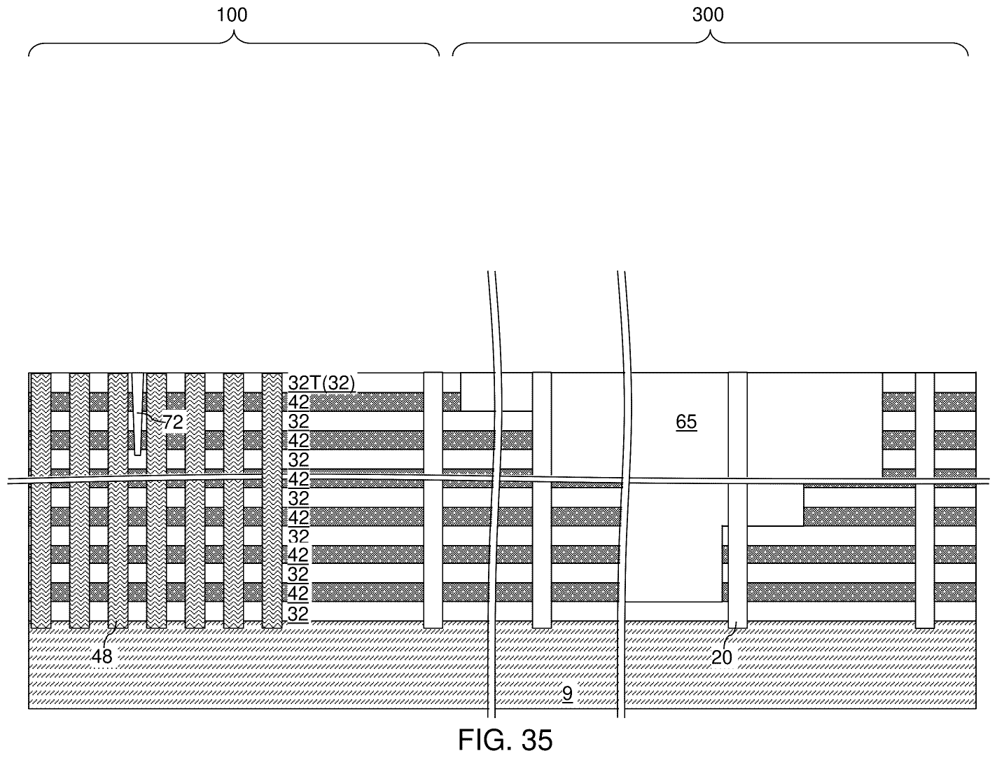

Referring to FIG. 28, the depths of rectangular horizontally-extending surface segments (i.e., steps) in a four row, 8 step contact well of another embodiment is illustrated in a plan view. The numbers represent the depth of each rectangular horizontally-extending surface segments (i.e., steps) is measured from the topmost surface of the alternating stack (32, 42) in units of the step height. Thus, FIG. 28 illustrates a case in which the contact well comprises a 4×8 rectangular array of rectangular horizontally-extending surface segments (i.e., steps).

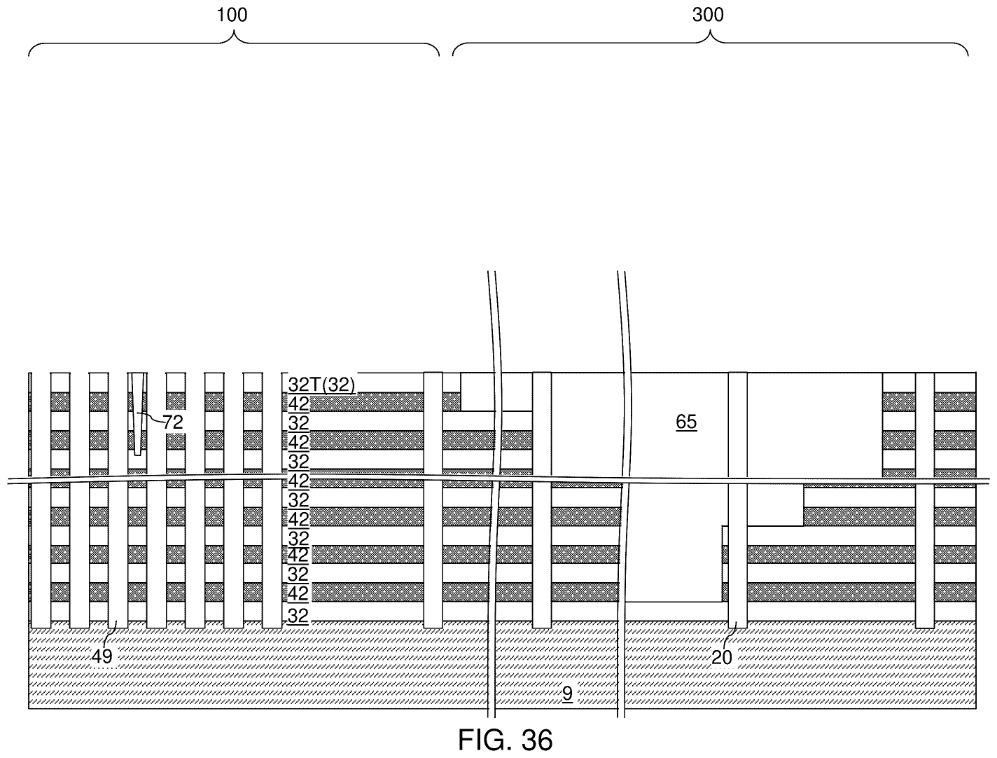

FIGS. 29A-29D are sequential vertical cross-sectional views of a 128 step contact well having a fourth configuration during a subset of processing steps according to an embodiment of the present disclosure. The fourth configuration can be provided by forming multiple instances of contact wells having the first configuration in tandem. The multiple instances of the contact wells can abut one another along the first horizontal direction hd1 or along the second horizontal direction hd2. Each number minus one represents the depth of the most vertically recessed rectangular horizontally-extending surface segment (i.e., step) around each location at which the number is shown. Specifically, the numbers represent 1 plus the ratio of the depth of the most vertically recessed rectangular horizontally-extending surface segment around each location at which the number is shown to the uniform vertical pitch. Eight 2×8 contact wells providing 16 different levels of rectangular horizontally-extending surface segments can be formed as shown in FIG. 29A, and can be vertically recessed by different recess depths that integer multiples of the product of 16 and the uniform vertical pitch. For example, four of the wells are extended by recessed by another 16 steps heights to form four wells that are 32 steps deep, as shown in FIG. 29B. Two of the extended wells are recessed twice by 16 steps to form two wells which are 64 steps deep, while two of the 16 step wells are recessed twice to form two wells which are 48 steps deep, as shown in FIG. 29C. Finally, the above recessing steps are repeated to merge eight wells which are respectively 16, 32, 48, 64, 80, 96, 112, and 128 steps deep into a single contact well. 128 different levels of rectangular horizontally-extending surface segments (i.e., steps) can be formed in the contact well.

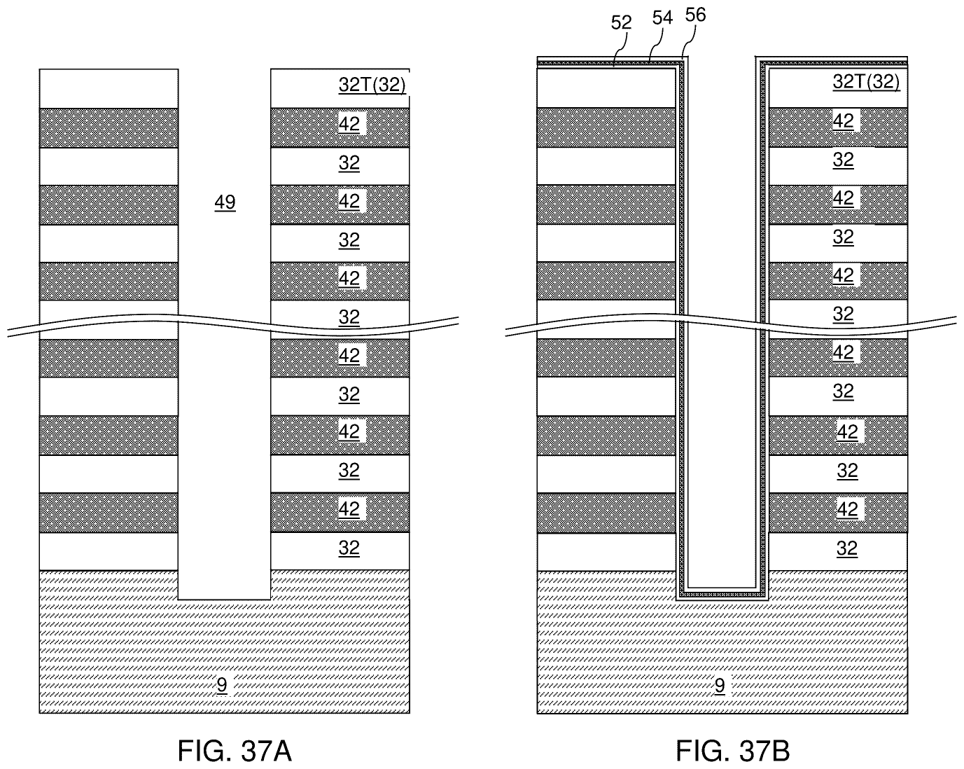

FIGS. 30A-30C are sequential vertical cross-sectional views of a 96 step contact well having a fifth configuration during a subset of processing steps according to an embodiment of the present disclosure. The fifth configuration can be provided by forming multiple instances of 24 step contact wells having the second configuration in tandem. The multiple instances of the contact wells can abut one another along the first horizontal direction hd1 or along the second horizontal direction hd2. Each number minus one represents the depth of the most vertically recessed rectangular horizontally-extending surface segment around each location at which the number is shown. Specifically, the numbers represent 1 plus the ratio of the depth of the most vertically recessed rectangular horizontally-extending surface segment around each location at which the number is shown to the uniform vertical pitch. Four 3×8 contact wells providing 24 different levels of rectangular horizontally-extending surface segments can be formed, and can be vertically recessed by different recess depths that integer multiples of the product of 24 and the uniform vertical pitch. 96 different levels of rectangular horizontally-extending surface segments (i.e., steps) can be formed in the contact well, as shown in FIG. 30C.

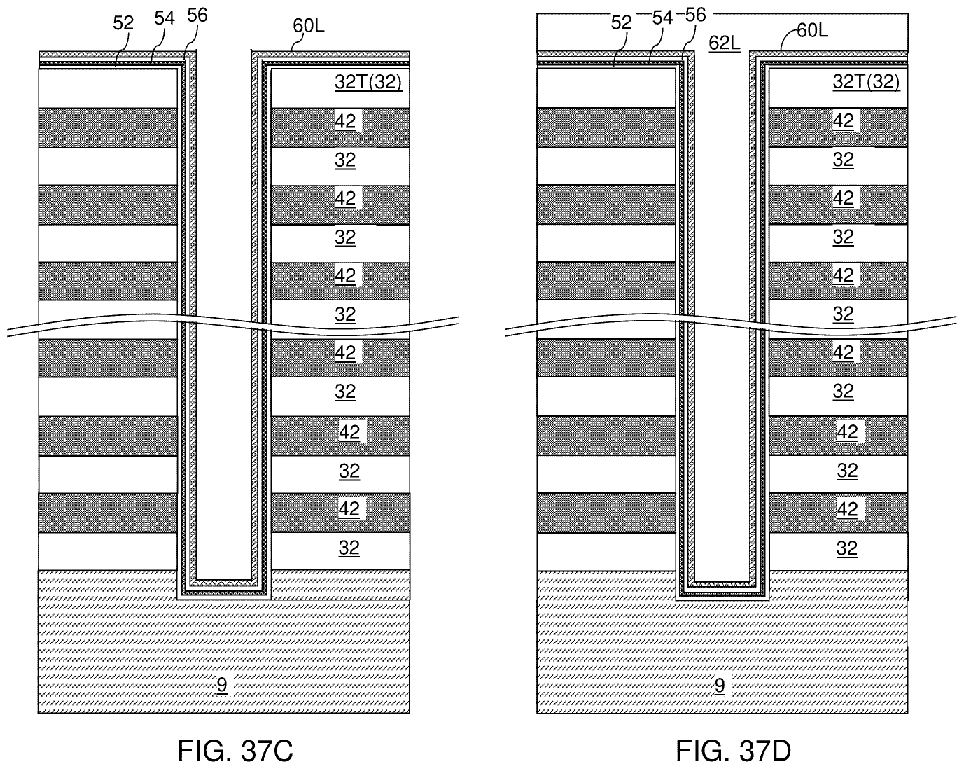

FIG. 31A is a schematic vertical cross-sectional view of the exemplary structure after formation of a stepped dielectric material portion according to an embodiment of the present disclosure. FIG. 31B is a top-down view of the exemplary structure of FIG. 31A. The hinged vertical cross-sectional plane A-A′ is the cut plane of the vertical cross-sectional view of FIG. 31A. Generally, a dielectric material portion (such as the stepped dielectric material portion 65) having a stepped bottom surface can be formed within the contact well. The top surface of the dielectric material portion may be formed within a horizontal plane including a topmost surface of the alternating stack (32, 42).

Referring to FIGS. 31A and 31B, a stepped dielectric material portion 65 (i.e., an insulating fill material portion) can be formed in the contact well by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F. The top surface of the stepped dielectric material portion 65 can be formed within a horizontal plane including the topmost surface of the alternating stack (32, 42). The stepped dielectric material portion 65 has a stepped bottom surface including rectangular horizontally-extending surface segments located at M×N different levels or more. The stepped bottom surface of the stepped dielectric material portion 65 may include rectangular horizontally-extending surface segments located at M×N different levels (as in the case of the first, second, and third configurations), or rectangular horizontally-extending surface segments located at integer multiple times M×N different levels (as in the case of the fourth or fifth configurations).

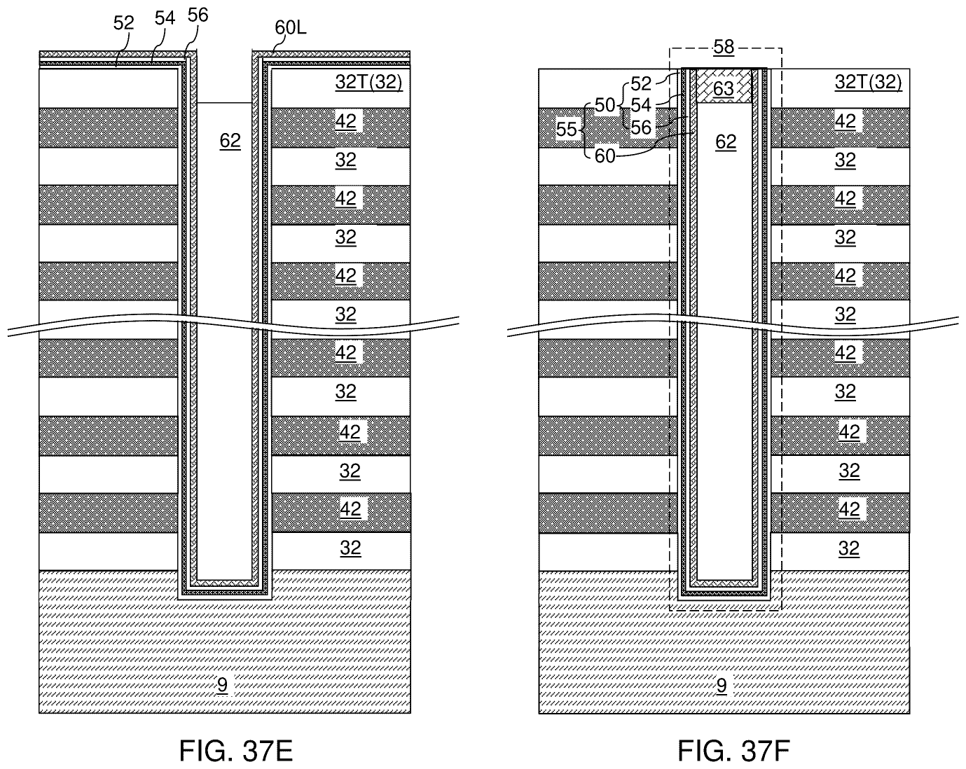

Referring to FIGS. 32A and 32B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater diameters may also be employed. The support openings 19 may have a diameter in a range from 60 nm to 400 nm, such as from 120 nm to 300 nm, although lesser and greater diameters may also be employed.

Each cluster of memory openings 49 (which corresponds to an area of a memory block) may comprise a plurality of rows of memory openings 49. Each row of memory openings 49 may comprise a plurality of memory openings 49 that are arranged along a horizontal direction (which may be a word line direction) with a uniform pitch. This horizontal direction may be the first horizontal direction hd1 or the second horizontal direction hd2. The rows of memory openings 49 may be laterally spaced from each other along another horizontal direction (which may be a bit line direction). In one embodiment, each cluster of memory openings 49 may be formed as a two-dimensional periodic array of memory openings 49.

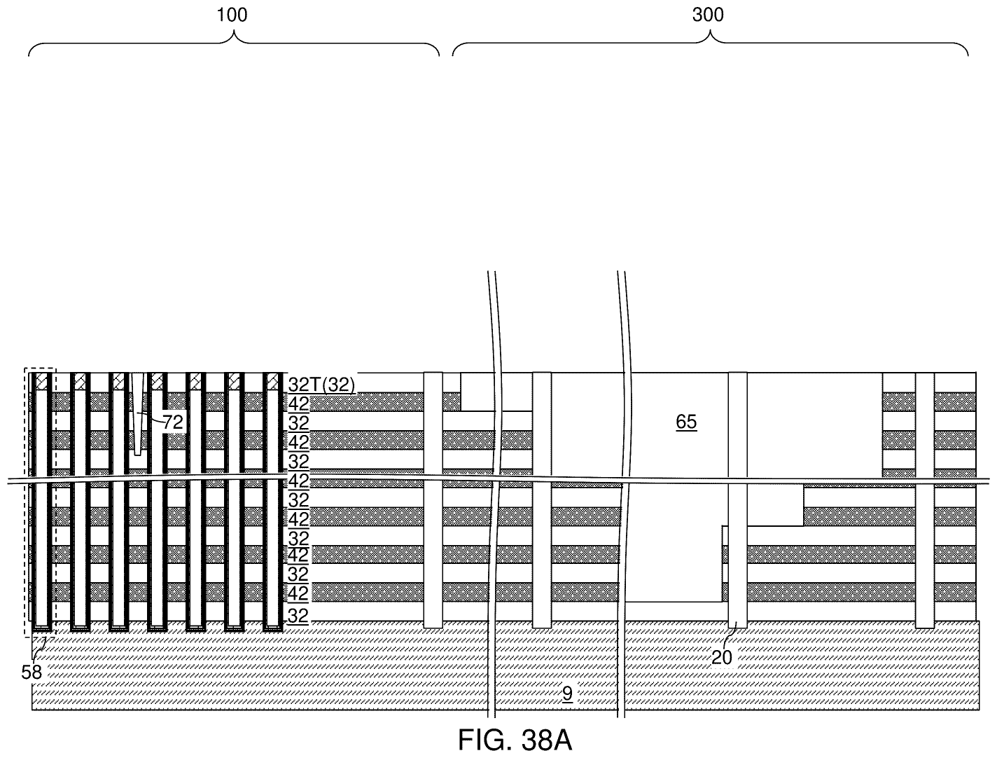

Referring to FIG. 33, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fill a support opening 19 constitutes a sacrificial support opening fill structure 18.

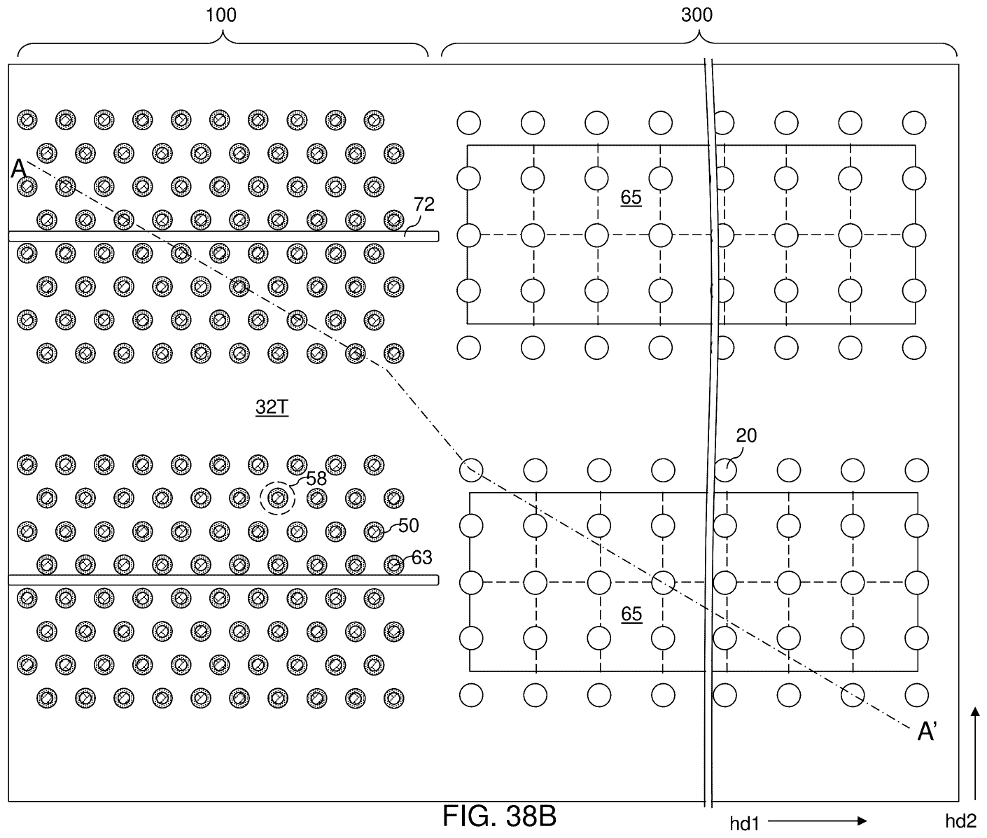

Referring to FIG. 34, a photoresist layer (not shown) can be applied over the exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed. The photoresist layer can be subsequently removed, for example, by ashing.

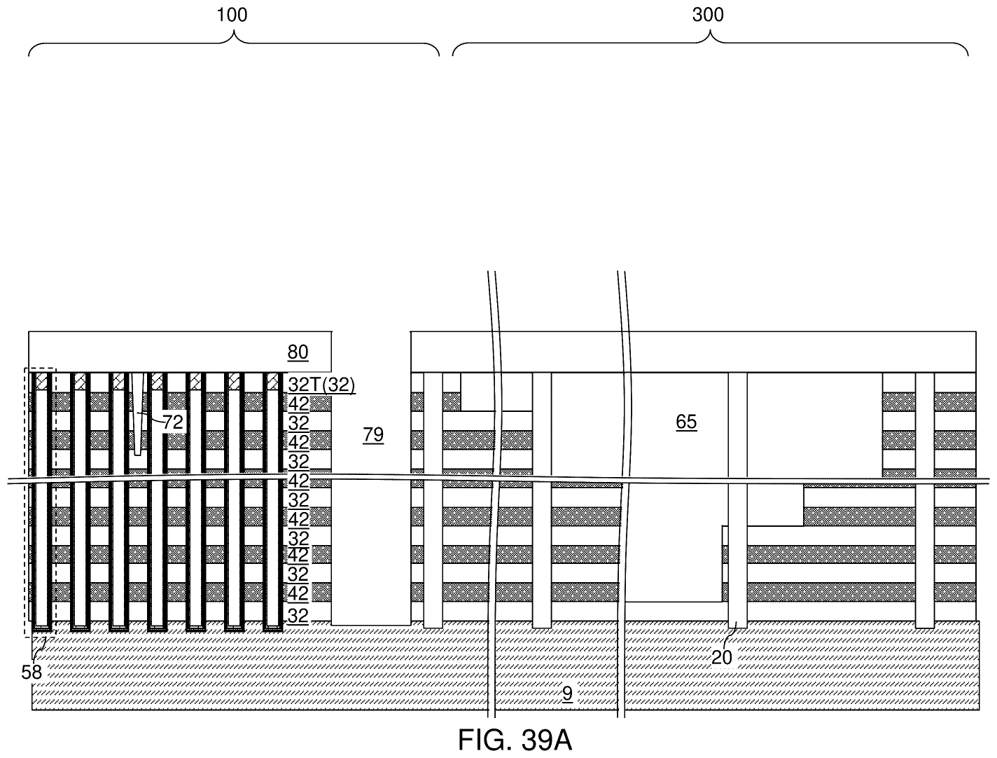

Referring to FIG. 35, a dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

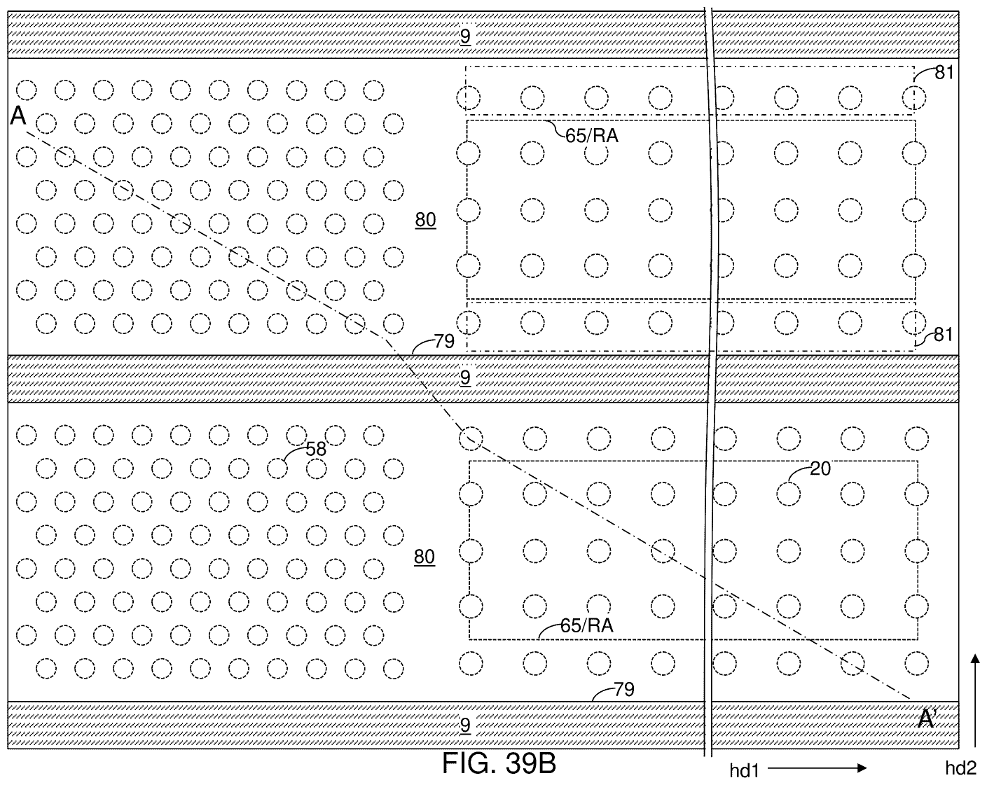

Referring to FIG. 36, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

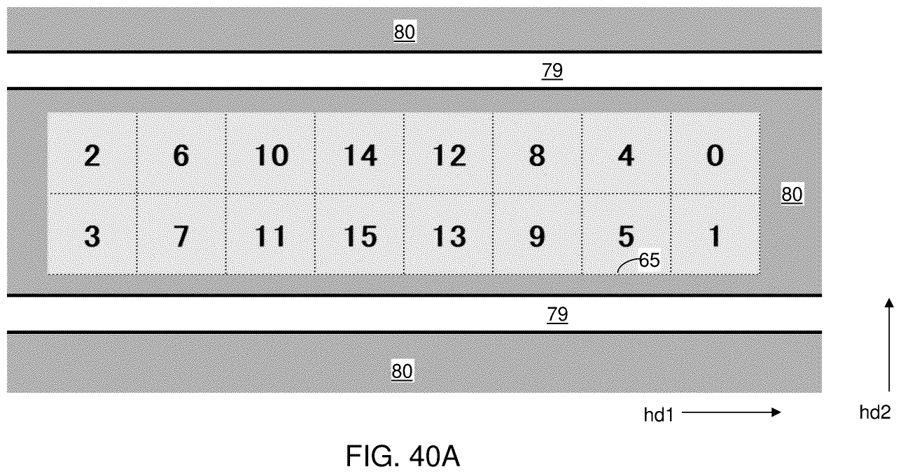

FIGS. 37A-37F are sequential vertical cross-sectional views of a memory opening 49 during formation of a memory opening fill structure 58 according to an embodiment of the present disclosure.

Referring to FIG. 37A, a memory opening 49 is illustrated after the processing steps of FIG. 36.

Referring to FIG. 37B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 37C, a semiconductor channel material layer 60L can be deposited over the memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 37D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 37E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 37F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extend predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the grains extend along the specific direction.

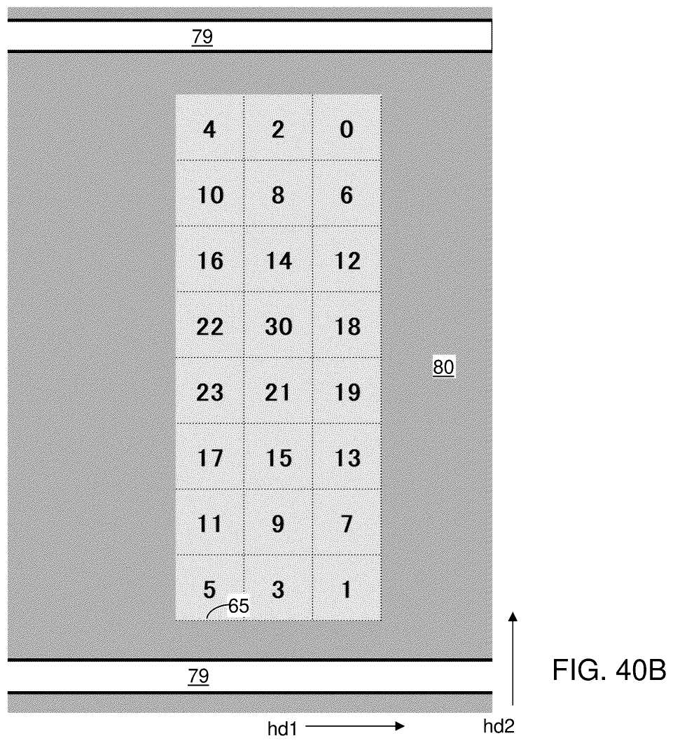

Referring to FIGS. 38A and 38B, the exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

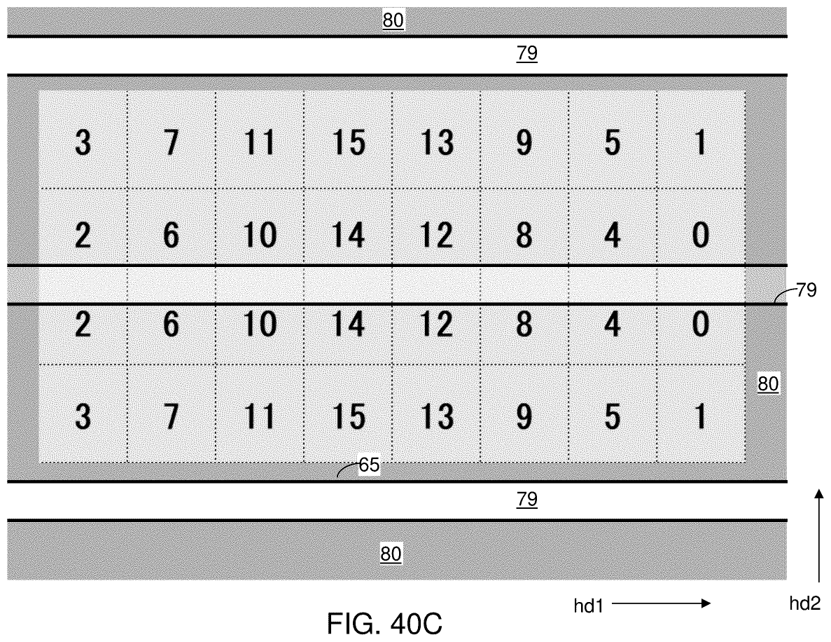

Referring to FIGS. 39A and 39B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along a horizontal direction between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and to a top surface of the carrier substrate 9. Lateral isolation trenches 79 laterally extending along a horizontal direction can be formed through the alternating stack (32, 42), the stepped dielectric material portion 65, and the contact-level dielectric layer 80. Each of the lateral isolation trenches 79 may comprise a respective pair of lengthwise sidewalls that are parallel to each other and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

In one embodiment, the lateral isolation trenches 79 may be formed through the alternating stack (32, 42) such that each rectangular area RA is located between a respective neighboring pair of lateral isolation trenches 79. In one embodiment shown in FIG. 39B, each rectangular area RA may be laterally spaced from the respective neighboring pair of lateral isolation trenches 79 by a pair of strip regions 81 in a remaining portion of the alternating stack (32, 42) that remains after formation of the lateral isolation trenches 79. The strip regions 81 ensure that portions of the alternating stack (32, 42) that are located at each side of the rectangular area are connected to each other. In other words, the presence of the strip regions 81 causes each spacer material layer (such as each sacrificial material layer 42) and each insulating layer 32 within the alternating stack (32, 42) to remain as a single contiguous structure so that each rectangular horizontally-extending surface segment of any spacer material layer is continuously connected to each part of the spacer material layer.

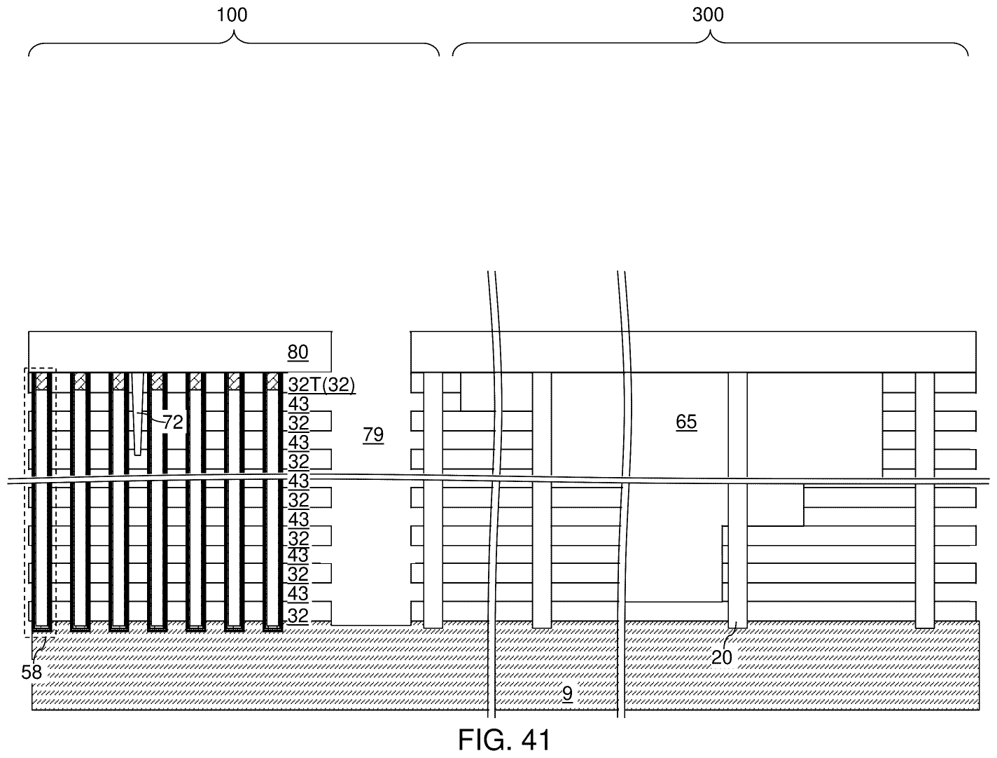

The lateral isolation trenches 79 laterally extend along the first horizontal direction hd1 and are laterally spaced apart among one another along the second horizontal direction hd2. In the embodiment illustrated in FIGS. 39B and 40A, the rows of steps in the contact wells are spaced from each other along the second horizontal direction hd2. FIG. 40B illustrates alternative embodiment in which the rows of steps in the contact wells are spaced from each other along the first horizontal direction hd1.

Alternatively, a subset of the lateral isolation trenches may cut through a respective contact well. Referring to FIG. 40C, an embodiment is illustrated in which the lateral isolation trenches 79 are formed through the alternating stack (32, 42) such that only one of the lateral isolation trenches 79 cuts through each rectangular area RA in a plan view. Thus, each patterned alternating stack (32, 42) may be laterally bounded by a first lateral isolation trench 79 to which a sidewall of a stepped dielectric material portion 65 is exposed, and by a second lateral isolation trench 79 which is laterally spaced from the stepped dielectric material portion 65 by a strip portion of the alternating stack (32, 42) in which each layer of the alternating stack (32, 42) is present.

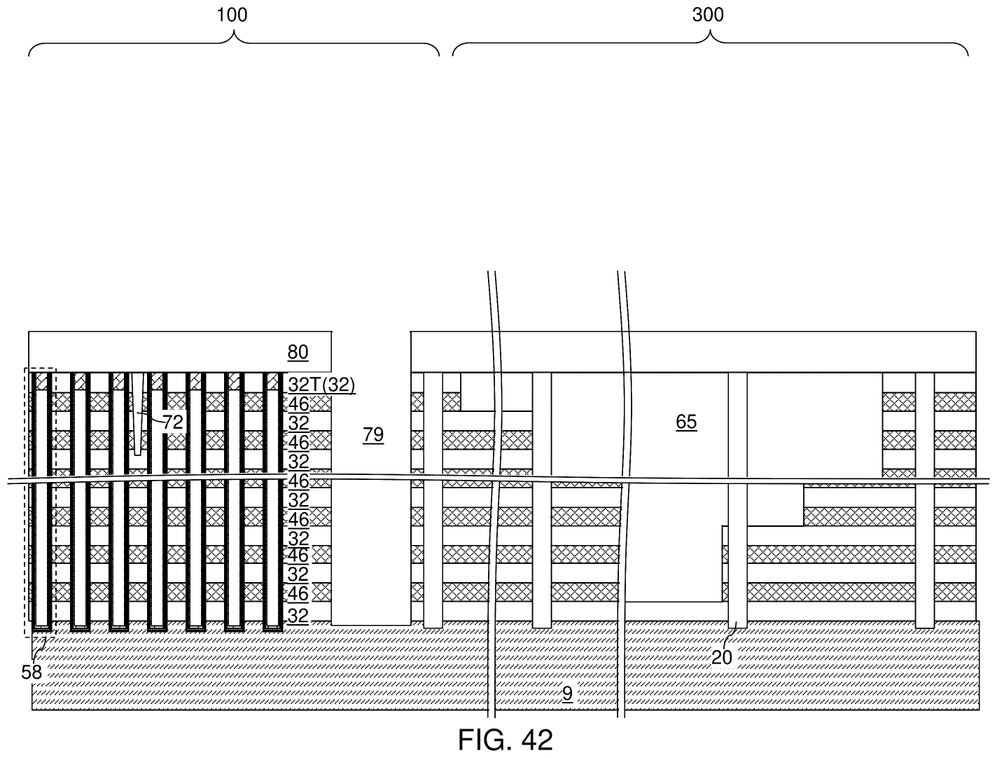

Referring to FIG. 41, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

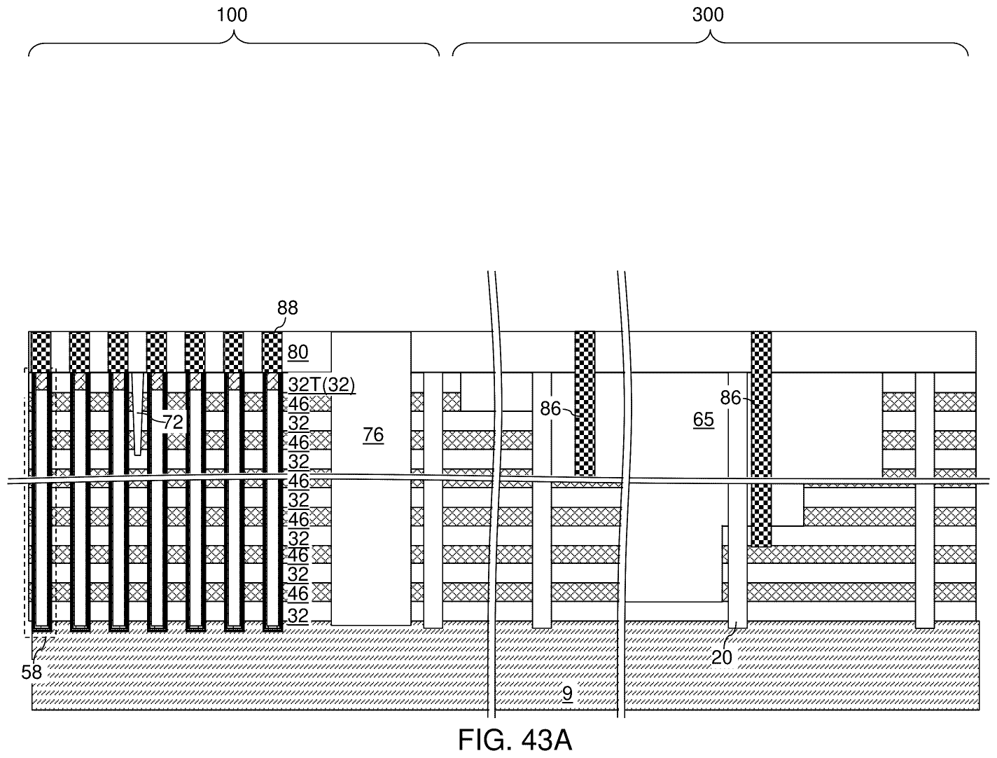

Referring to FIG. 42, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the lateral isolation trenches 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58). Generally, an alternating stack (32, 46) of insulating layers 32 and electrically conductive layers 46 can be formed between each neighboring pair of lateral isolation trenches 79.

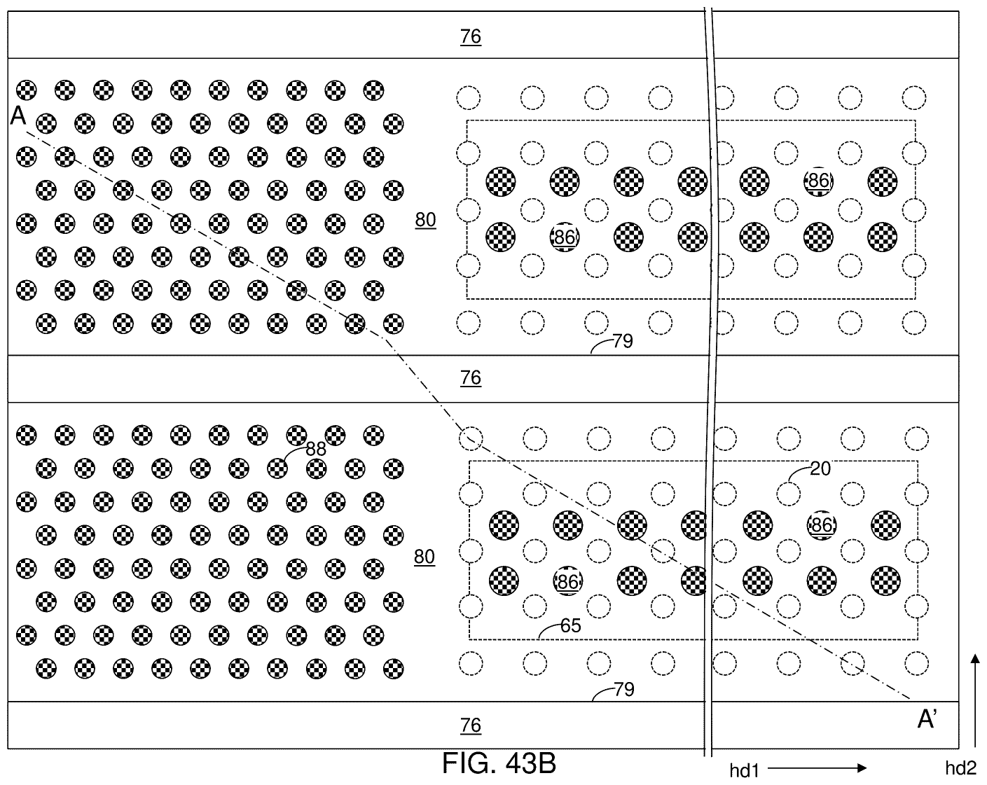

Referring to FIGS. 43A and 43B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

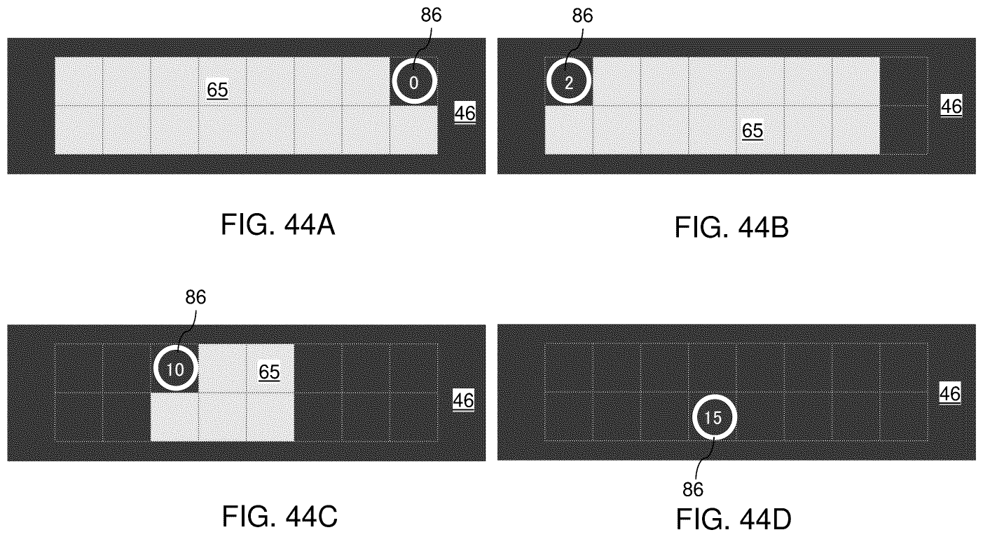

Referring to FIGS. 44A-44D, various horizontal cross-sectional views of the exemplary structure of the two row, 16 step contact well having the first configuration of FIGS. 43A and 43B are illustrated at various levels according to embodiments of the present disclosure. FIG. 44A is a horizontal cross-sectional view at the level of the topmost electrically conductive layer 46, which is contacted by a layer contact structure 86 labeled with an identification number “0.” FIG. 44B is a horizontal cross-sectional view at the level of the electrically conductive layer 46 that is the third as counted from the top. This electrically conductive layer 46 is contacted by a layer contact structure 86 labeled with an identification number “2.” FIG. 44C is a horizontal cross-sectional view at the level of the electrically conductive layer 46 that is the eleventh as counted from the top. This electrically conductive layer 46 is contacted by a layer contact structure 86 labeled with an identification number “10.” FIG. 44D is a horizontal cross-sectional view at the level of the bottommost electrically conductive layer 46 that is the sixteenth as counted from the top. This electrically conductive layer 46 is contacted by a layer contact structure 86 labeled with an identification number “15.”

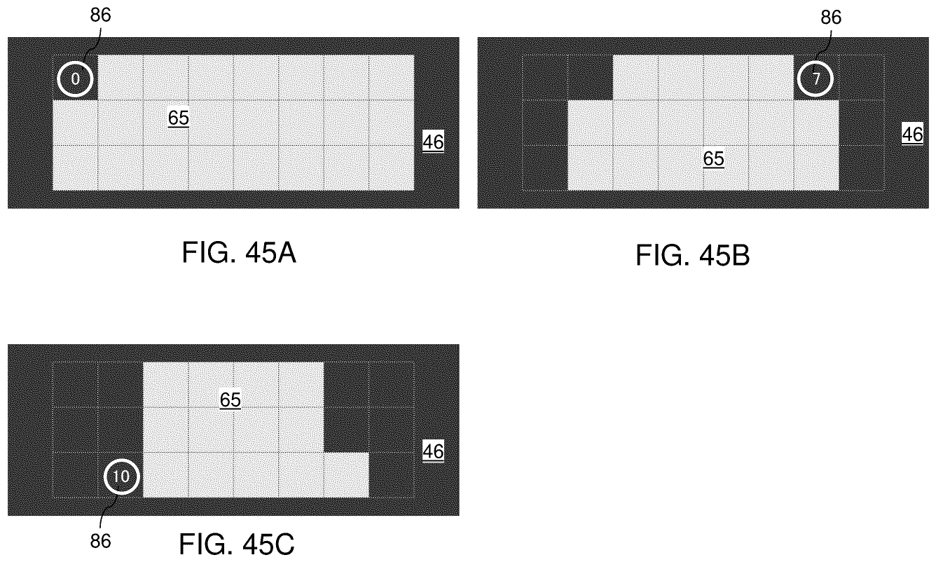

Referring to FIGS. 45A-45C, various horizontal cross-sectional views of the exemplary structure of the three row, 24 step contact well having in the second configuration of FIGS. 43A and 43B are illustrated at various levels according to embodiments of the present disclosure. FIG. 45A is a horizontal cross-sectional view at the level of the topmost electrically conductive layer 46, which is contacted by a layer contact structure 86 labeled with an identification number “0.” FIG. 45B is a horizontal cross-sectional view at the level of the electrically conductive layer 46 that is the eighth as counted from the top. This electrically conductive layer 46 is contacted by a layer contact structure 86 labeled with an identification number “7.” FIG. 45C is a horizontal cross-sectional view at the level of the electrically conductive layer 46 that is the eleventh as counted from the top. This electrically conductive layer 46 is contacted by a layer contact structure 86 labeled with an identification number “10.”

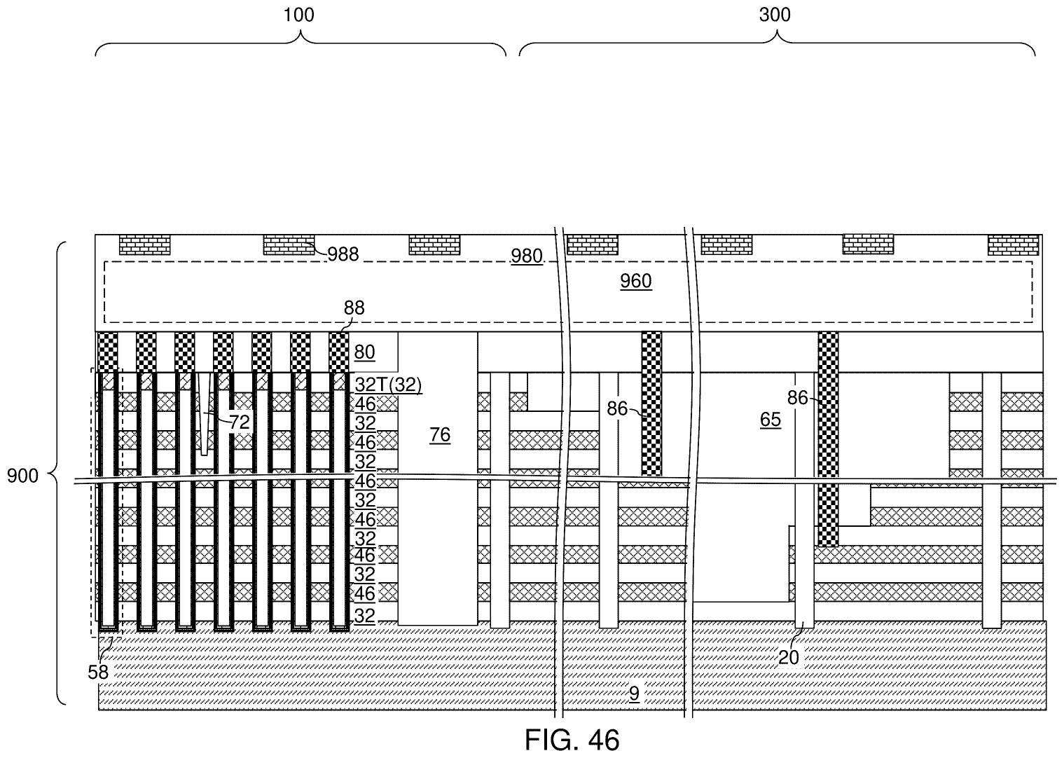

Referring to FIG. 46, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

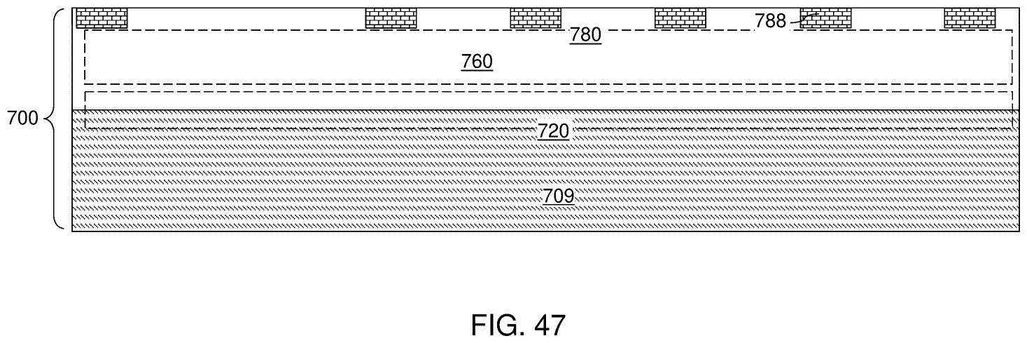

Referring to FIG. 47, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

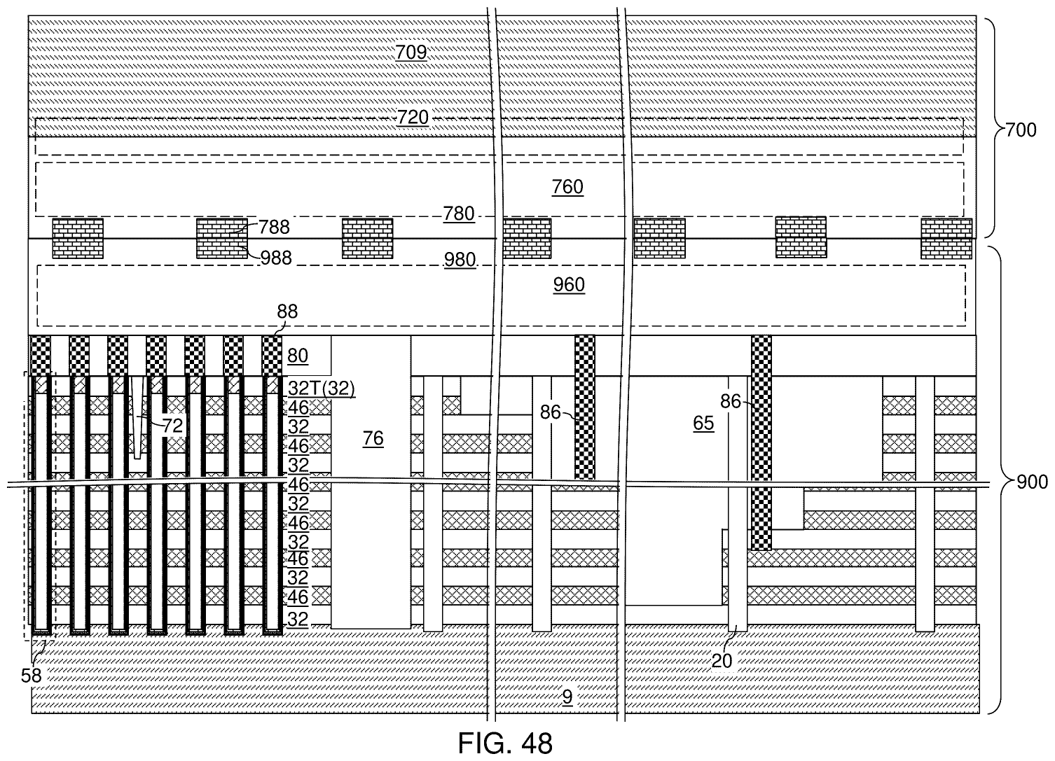

Referring to FIG. 48, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

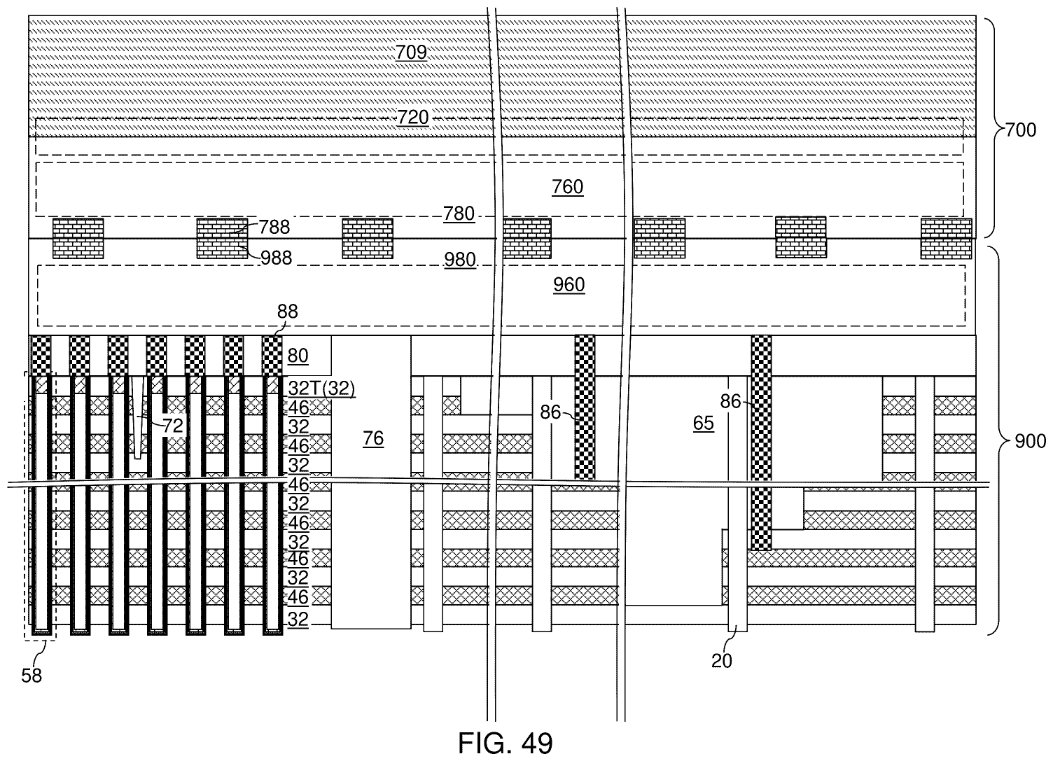

Referring to FIG. 49, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9.

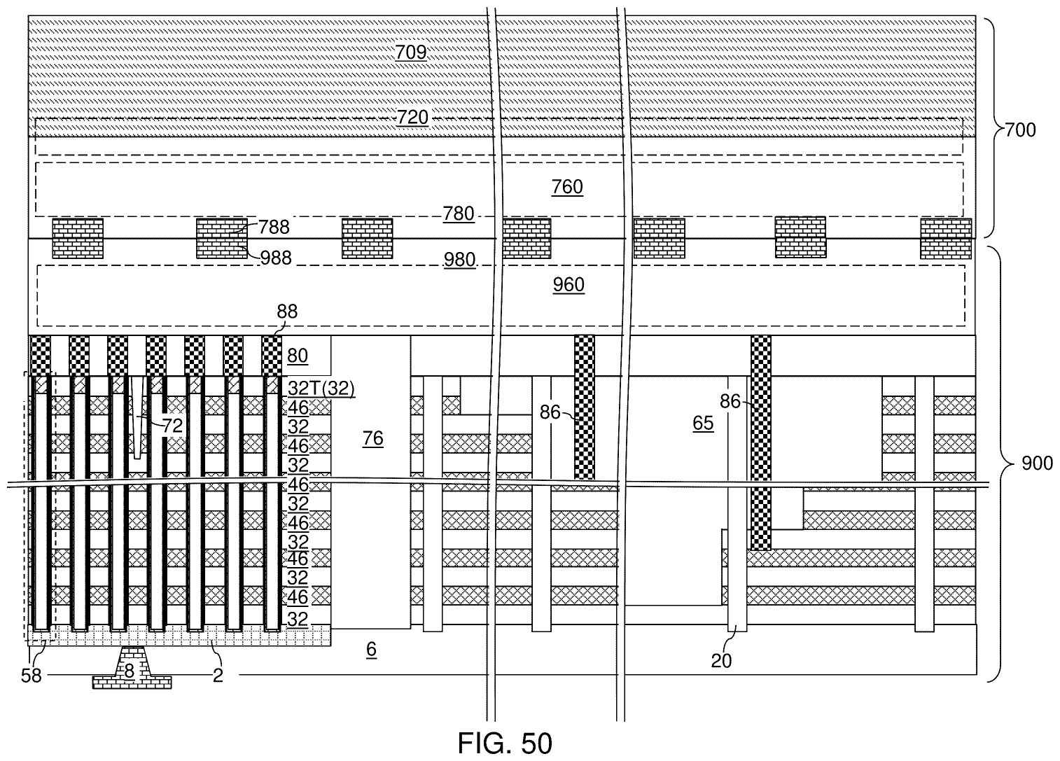

Referring to FIG. 50, a sequence of wet etch steps can be performed to sequentially remove portions of the memory film 50 that are exposed on the backside of the alternating stack (32, 46). For example, the blocking dielectric layer 52, the memory material layer 54, and the optional dielectric liner 56 (which may be, for example, a tunneling dielectric layer) of each memory film 50 can be removed from a region that is more distal from the bonding interface between the memory die 900 and the logic die 700 than a physically exposed planar surface of the bottommost insulating layer 32B is from the bonding interface. For the purpose of convenience, geometrical features of the exemplary structure and other exemplary structures in the present disclosure may be described in an orientation in which the logic die 700 overlies the memory die 900. Viewed in this orientation, the blocking dielectric layer 52, the memory material layer 54, and the optional dielectric liner 56 (which may be, for example, a tunneling dielectric layer) of each memory film 50 can be removed from below the horizontal plane including the bottom surface of the bottommost insulating layer 32B.

A doped semiconductor and/or metallic material layers are deposited over the bottom surface of the bottommost insulating layer 32B and then patterned to form a source layer 2. A backside insulating layer 6 can be formed over the source layer 2, and backside contact pad structures 8 can be formed through the backside insulating layer 6 in contact with the source layer 2.

The methods of the embodiments of the present disclosure form compact staircases with plural rows of steps without complex photoresist patterning or trimming. A terrace is formed without photoresist trimming followed by etching the alternating stack. The photoresist layers have a simple pattern with relatively low step height. This reduces the variability in the area of the steps.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A method of forming a device structure, comprising:
forming an alternating stack of insulating layers and spacer material layers over a substrate, wherein: the spacer material layers are formed as or are subsequently replaced with electrically conductive layers, wherein the alternating stack comprises a contact region comprising rectangular area in a plan view and a surrounding area that surrounds the rectangular area, and wherein the rectangular area comprises a periphery including a pair of lengthwise sides laterally extending along a first horizontal direction and a pair of widthwise sides laterally extending along a second horizontal direction in a plan view;
forming at least one lengthwise step laterally extending along the first horizontal direction between the pair of widthwise sides of the rectangular area of the alternating stack, wherein each horizontal surface segment within the rectangular area of the alternating stack is formed at M different levels, wherein M is an integer in a range from 2 to 6; and
forming a plurality of widthwise steps laterally extending along the second horizontal direction between the pair of lengthwise sides of the rectangular area of the alternating stack by performing multiple instances of a stepped surface formation processing sequence, wherein each instance of the stepped surface formation processing sequence comprises a respective masking process in which a respective photoresist layer is applied over the alternating stack and is lithographically patterned to partially mask the rectangular area and completely mask the surrounding area and to provide a respective sidewall that extends over the rectangular area along the second horizontal direction, a respective anisotropic etch process that etches respective portions of the alternating stack that are not masked by the respective photoresist layer by a respective recess etch depth, and a respective photoresist removal process that removes the respective photoresist layer.

2. The method of claim 1, wherein:
each of the insulating layers has a first thickness;
each of the spacer material layers has a second thickness;
a sum of the first thickness and the second thickness comprises a step height; and
the respective recess etch depth equals to a product of a respective positive integer, said M, and the step height.

3. The method of claim 2, wherein:
the respective positive integer is 1 for at least one instance of the instances of the stepped surface formation processing sequence; and
the respective positive integer is 2 for at least another instance of the instances of the stepped surface formation processing sequence.

4. The method of claim 2, wherein:
the respective photoresist layer comprises a rectangular opening such that the respective sidewall of the respective photoresist layer comprises a sidewall of the at least one rectangular opening;
the rectangular opening of the respective photoresist layer comprises additional sidewalls that coincide with segments of the pair of lengthwise sides of the rectangular area in the plan view.

5. The method of claim 2, wherein said M has a value selected from 2 and 3.

6. The method of claim 2, wherein the at least one lengthwise step is formed by:
applying a respective additional photoresist layer over the alternating stack;
forming a respective elongated rectangular opening in the respective additional photoresist layer to provide a sidewall that laterally extends along the first horizontal direction over the rectangular area; and
recessing portions of the alternating stack located within the respective elongated opening by a respective recess etch distance.

7. The method of claim 6, wherein each recess etch distance employed to form the at least one lengthwise step is a product of a respective positive integer and the sum of the first thickness and the second thickness.

8. The method of claim 6, wherein each additional photoresist layer has a pair of widthwise sidewalls that coincide with the pair of widthwise sides of the rectangular area in the plan view.

9. The method of claim 1, wherein:
the insulating layers comprise a first material;
the spacer material layers comprise a second material; and
each anisotropic etch process within the multiple instances of the stepped surface formation processing sequence comprises an alternating sequence of a first-type anisotropic etch step that etches the first material selective to the second material and a second-type anisotropic etch step that etches the second material selective to the first material.

10. The method of claim 2, wherein a contact well is formed within the rectangular area through formation of the at least one lengthwise step and formation of the plurality of widthwise steps, wherein peripheral sidewalls of the contact well are formed at the pair of lengthwise sides and at the pair of widthwise sides of the rectangular area in the plan view.

11. The method of claim 10, wherein a vertical cross-sectional profile of the contact well along the first horizontal direction comprises:
a descending staircase profile that extends along the first horizontal direction from a first sidewall of the contact well located at one of the pair of widthwise sides of the rectangular area to a bottommost horizontal surface segment of the descending staircase profile; and
an ascending staircase profile that extends along the first horizontal direction from the bottommost horizontal surface segment of the ascending staircase profile to a second sidewall of the contact well located at another of the pair of widthwise sides of the rectangular area.

12. The method of claim 10, further comprising forming a dielectric material portion having a stepped bottom surface within the contact well, wherein a top surface of the dielectric material portion is formed within a horizontal plane including a topmost surface of the alternating stack.

13. The method of claim 10, wherein:
the contact well comprises a total of M×N array of rectangular horizontal surface segments that are vertically offset from each other, wherein N is an integer greater than M;
the rectangular horizontal surface segments comprise steps;
the contact well comprises M rows of N steps each; and
each of the M rows of steps is laterally offset relative any other ones of M rows steps by a respective uniform vertical offset distance that is invariant along the first horizontal direction, the respective uniform vertical offset distance being an integer multiple of the step height.

14. The method of claim 13, further comprising forming lateral isolation trenches through the alternating stack such that the rectangular area is located between a neighboring pair of lateral isolation trenches, wherein the lateral isolation trenches laterally extend along the first horizontal direction and are laterally spaced apart from each other along the second horizontal direction.

15. The method of claim 14, wherein the rectangular area is laterally spaced from the neighboring pair of lateral isolation trenches by a pair of strip regions in a remaining portion of the alternating stack.

16. The method of claim 14, wherein the M rows extends along the first horizontal direction.

17. The method of claim 14, wherein the M rows extend along the second horizontal direction.

18. The method of claim 13, further comprising:
forming memory openings vertically extending through the alternating stack;
forming memory opening fill structures located in the memory openings, wherein each of the memory opening fill structures comprises a respective vertical stack of memory elements and a vertical semiconductor channel; and
forming vertically extending layer contact via structures which contact a respective one of the electrically conductive layers at a respective one of the steps.

19. The method of claim 1, wherein each of the respective photoresist layers is patterned only once without trimming, and is used as an etch mask only once during the respective anisotropic etch process that etches respective portions of the alternating stack, prior to the respective photoresist removal process.

20. The method of claim 1, further comprising forming lateral isolation trenches through the alternating stack such that only one of the lateral isolation trenches cuts through the rectangular area in a plan view.
